(19) United States
(12) Patent Application Publication
(10) Pub. No.: US 2023/0215897 A1
(43) Pub. Date: Jul. 6, 2023

(54) IMAGING ELEMENT AND ELECTRONIC DEVICE

(71) Applicant: SONY SEMICONDUCTOR SOLUTIONS CORPORATION, KANAGAWA (JP)

(72) Inventor: MASATAKA SATO, TOKYO (JP)

(21) Appl. No.: 18/001,013

(22) PCT Filed: Jun. 2, 2021
(86) PCT No.: PCT/JP2021/020996

§ 371 Date: Dec. 7, 2022

(30) Foreign Application Priority Data
Jun. 16, 2020 (JP) 2020-103745

(51) Int. Cl. H01L 27/146; H04N 25/633; H04N 25/702; H04N 25/79

(52) U.S. Cl. CPC H01L 27/14636; H04N 25/79; H04N 25/633; H04N 25/702; H01L 27/1463; H01L 27/14645; H04N 25/78

(57) ABSTRACT

The present technology relates to an imaging element and an electronic device capable of preventing light from leaking into an adjacent pixel. A semiconductor layer in which a first pixel in which a read pixel signal is used to generate an image, and a second pixel in which the read pixel signal is not used to generate an image are arranged, and a wiring layer stacked on the semiconductor layer are provided, and a structure of the first pixel and a structure of the second pixel are different. A first inter-pixel separation portion that separates the semiconductor layer of the adjacent first pixels, and a second inter-pixel separation portion that separates the semiconductor layer of the adjacent second pixels are further provided, and the first inter-pixel separation portion and the second inter-pixel separation portion are provided with different structures. The present technology can be applied to an imaging element in which dummy pixels are arranged.

### TECHNICAL FIELD

The present technology relates to an imaging element and an electronic device, and for example, relates to an imaging element and an electronic device that suppress light leaking into an adjacent pixel.

### BACKGROUND ART

In a video camera, a digital still camera, or the like, an imaging device including a charge coupled device (CCD) or a CMOS image sensor is widely used. In these imaging devices, a light receiving section including a photodiode is formed for each pixel, and signal charges are generated by photoelectric conversion of incident light in the light receiving section.

In such an imaging device, there is a possibility that a false signal is generated in the semiconductor substrate by oblique incident light or incident light diffusely reflected at the upper portion of the light receiving section, and optical noise such as smear or flare occurs. Patent Document 1 proposes suppression of optical noise such as flare and smear without deteriorating light collection characteristics.

### CITATION LIST

### Patent Document

Patent Document 1: Japanese Patent Application Laid-Open No. 2012-33583

### SUMMARY OF THE INVENTION

### Problems to be Solved by the Invention

Patent Document 1 describes that the pixel region includes an effective pixel region that actually receives light, amplifies signal charges generated by photoelectric conversion, and reads the signal charges to the column signal processing circuit, and an optical black region for outputting optical black serving as a reference of a black level.

If light leaks into the optical black region, there is a possibility that the accuracy of the black level reference is reduced. It is desired to further suppress leakage of light into the optical black region.

The present technology has been made in view of such a situation, and an object thereof is to suppress leakage of light into an optical black region.

### Solutions to Problems

An imaging element according to one aspect of the present technology includes: a semiconductor layer in which a first pixel in which a read pixel signal is used to generate an image, and a second pixel in which the read pixel signal is not used to generate an image are arranged; and a wiring layer stacked on the semiconductor layer, and a structure of the first pixel and a structure of the second pixel are different.

An electronic device according to one aspect of the present technology includes: an imaging element including a semiconductor layer in which a first pixel in which a read pixel signal is used to generate an image, and a second pixel in which the read pixel signal is not used to generate an image are arranged, and a wiring layer stacked on the semiconductor layer, in which a structure of the first pixel and a structure of the second pixel are different; and a distance measuring module including a light source that emits irradiation light whose brightness varies periodically, and a light emission control section that controls an irradiation timing of the irradiation light.

In an imaging element according to one aspect of the present technology, a semiconductor layer in which a first pixel in which a read pixel signal is used to generate an image, and a second pixel in which the read pixel signal is not used to generate an image are arranged, and a wiring layer stacked on the semiconductor layer are provided. Furthermore, a structure of the first pixel and a structure of the second pixel are different.

In an electronic device according to one aspect of the present technology, the imaging element and a distance measuring module including a light source that emits irradiation light whose brightness varies periodically, and a light emission control section that controls an irradiation timing of the irradiation light are provided.

Note that the electronic device may be an independent device or an internal block constituting one device.

### BRIEF DESCRIPTION OF DRAWINGS

FIG. 1 is a diagram illustrating a schematic configuration of an imaging device according to the present disclosure.

FIG. 2 is a diagram for explaining a pixel region of a pixel array unit.

FIG. 3 is a diagram for explaining arrangement of pixels in the pixel array unit.

FIG. 4 is a cross-sectional configuration example of a pixel of the pixel array unit.

FIG. 5 is a cross-sectional configuration example of a pixel of the pixel array unit.

FIG. 6 is a diagram illustrating another schematic configuration of the imaging device.

FIG. 7 is a cross-sectional configuration example of a pixel of the pixel array unit.

FIG. 8 is a cross-sectional configuration example of a pixel of the pixel array unit.

FIG. 9 is a cross-sectional configuration example of a pixel of the pixel array unit.

FIG. 10 is a circuit diagram of an imaging element.

FIG. 11 is a plan view of the imaging element.

FIG. 12 is a diagram for explaining leakage of light from an adjacent pixel.

FIG. 13 is a cross-sectional configuration example of the imaging element in a first embodiment.

FIG. 14 is a planar configuration example of the imaging element in the first embodiment.

FIG. 15 is a cross-sectional configuration example of an imaging element in a second embodiment.

FIG. 16 is a planar configuration example of the imaging element in the second embodiment.

FIG. 17 is a cross-sectional configuration example of an imaging element in a third embodiment.

FIG. 18 is a planar configuration example of the imaging element in the third embodiment.

FIG. 19 is a cross-sectional configuration example of an imaging element in a fourth embodiment.

FIG. 20 is a cross-sectional configuration example of an imaging element in a fifth embodiment.

FIG. 21 is a planar configuration example of the imaging element in the fifth embodiment.

FIG. 22 is a cross-sectional configuration example of an imaging element in a sixth embodiment.

FIG. 23 is a planar configuration example of the imaging element in the sixth embodiment.

FIG. 24 is a cross-sectional configuration example of an imaging element in a seventh embodiment.

FIG. 25 is a cross-sectional configuration example of an imaging element in an eighth embodiment.

FIG. 26 is a planar configuration example of the imaging element in the eighth embodiment.

FIG. 27 is a cross-sectional configuration example of an imaging element in a ninth embodiment.

FIG. 28 is a planar configuration example of the imaging element in the ninth embodiment.

FIG. 29 is a cross-sectional configuration example of an imaging element in a tenth embodiment.

FIG. 30 is a planar configuration example of the imaging element in the tenth embodiment.

FIG. 31 is a cross-sectional configuration example of an imaging element in an eleventh embodiment.

FIG. 32 is a cross-sectional configuration example of an imaging element in a twelfth embodiment.

FIG. 33 is a diagram illustrating a configuration example of a distance measuring module.

FIG. 34 is a diagram illustrating a configuration example of an electronic device.

FIG. 35 is a block diagram depicting an example of a schematic configuration of a vehicle control system.

FIG. 36 is a diagram of assistance in explaining an example of installation positions of an outside-vehicle information detecting section and an imaging section.

### MODE FOR CARRYING OUT THE INVENTION

Modes for carrying out the present technology (hereinafter, referred to as an embodiment) will be described below.

### Schematic Configuration Example of Imaging Device

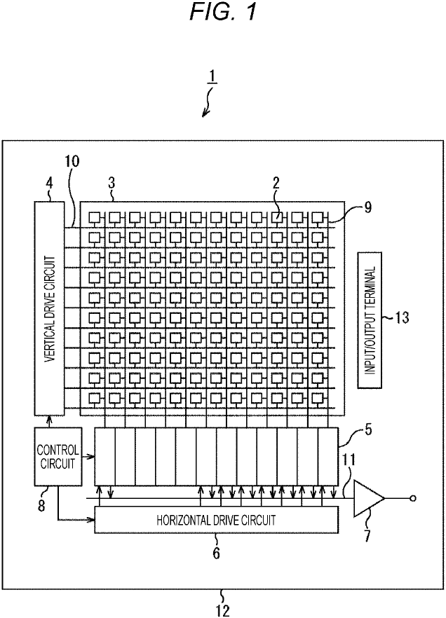

FIG. 1 illustrates a schematic configuration of an imaging device including an imaging element according to the present disclosure.

An imaging device 1 of FIG. 1 includes a pixel array unit 3 in which pixels 2 are arranged in a two-dimensional array and a peripheral circuit unit around the pixel array unit 3 on a semiconductor substrate 12 using, for example, silicon (Si) as a semiconductor. The peripheral circuit unit includes a vertical drive circuit 4, a column signal processing circuit 5, a horizontal drive circuit 6, an output circuit 7, a control circuit 8, and the like.

The pixel 2 includes a photodiode as a photoelectric conversion element and a plurality of pixel transistors. The plurality of pixel transistors includes, for example, four MOS transistors of a transfer transistor, a selection transistor, a reset transistor, and an amplification transistor.

Furthermore, the pixel 2 may have a shared pixel structure. This pixel sharing structure includes a plurality of photodiodes, a plurality of transfer transistors, one shared floating diffusion (floating diffusion region), and one shared other pixel transistor. That is, in the shared pixel, the photodiode and the transfer transistor constituting the plurality of unit pixels are configured to share each other pixel transistor.

The control circuit 8 receives an input clock and data instructing an operation mode or the like, and outputs data such as internal information of the imaging device 1. That is, the control circuit 8 generates a clock signal or a control signal serving as a reference of operations of the vertical drive circuit 4, the column signal processing circuit 5, the horizontal drive circuit 6, and the like on the basis of a vertical synchronization signal, a horizontal synchronization signal, and a master clock. Then, the control circuit 8 outputs the generated clock signal and control signal to the vertical drive circuit 4, the column signal processing circuit 5, the horizontal drive circuit 6, and the like.

The vertical drive circuit 4 includes, for example, a shift register, selects a pixel drive wiring 10, supplies a pulse for driving the pixels 2 to the selected pixel drive wiring 10, and drives the pixels 2 in units of rows. That is, the vertical drive circuit 4 sequentially selects and scans each pixel 2 of the pixel array unit 3 in the vertical direction in units of rows, and supplies a pixel signal based on a signal charge generated in accordance with a received light amount in a photoelectric conversion part of each pixel 2 to the column signal processing circuit 5 through a vertical signal line 9.

The column signal processing circuit 5 is arranged for each column of the pixels 2, and performs signal processing such as noise removal on the signals output from the pixels 2 of one row for each pixel column. For example, the column signal processing circuit 5 performs signal processing such as correlated double sampling (CDS) for removing pixel-specific fixed pattern noise and AD conversion.

The horizontal drive circuit 6 includes, for example, a shift register, sequentially selects each of the column signal processing circuits 5 by sequentially outputting horizontal scanning pulses, and causes each of the column signal processing circuits 5 to output a pixel signal to a horizontal signal line 11.

The output circuit 7 performs signal processing on the signals sequentially supplied from each of the column signal processing circuits 5 through the horizontal signal line 11, and outputs the processed signals. For example, the output circuit 7 may perform only buffering, or may perform black level adjustment, column variation correction, various digital signal processing, and the like. An input/output terminal 13 exchanges signals with the outside.

The imaging device 1 configured as described above is a CMOS image sensor called a column AD system in which the column signal processing circuits 5 that perform CDS processing and AD conversion processing are arranged for each pixel column.

Furthermore, the imaging device 1 is a back-illuminated MOS imaging device in which light is incident from the back surface side opposite to the front surface side of the semiconductor substrate 12 on which the pixel transistors are formed.

### Configuration Example of Pixel Array Unit 3

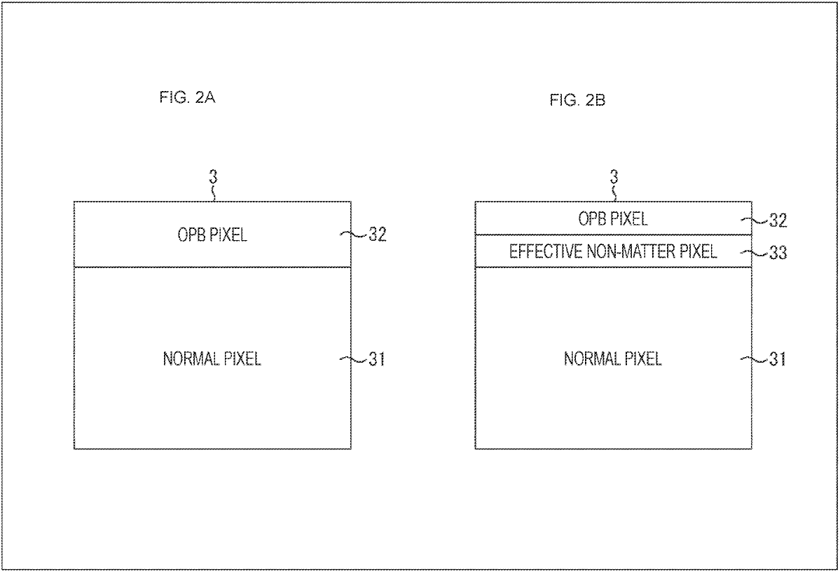

FIG. 2 is a diagram illustrating a configuration example of the pixel array unit 3 of the imaging device 1.

In the pixel array unit 3 illustrated in A of FIG. 2, a normal pixel region 31 in which normal pixels are arranged and an optical black (OPB) pixel region 32 in which optical black (OPB) pixels are arranged are arranged. The OPB pixel region 32 arranged at the upper end (in the drawing) of the pixel array unit 3 is a light shielding region shielded from light so that light does not enter. The normal pixel region 31 is an opening region that is not shielded from light.

In the normal pixel region 31 arranged in the opening region, normal pixels (hereinafter, described as a normal pixel 31) from which pixel signals are read when an image is generated are arranged.

In the OPB pixel region 32 arranged in the upper light-shielding region, OPB pixels (hereinafter, described as OPB pixels 32) used for reading a black level signal which is a pixel signal indicating a black level of an image are arranged.

In the pixel array unit 3 illustrated in B of FIG. 2, an effective non-matter pixel region 33 in which effective non-matter pixels 33 are arranged is provided between the normal pixel region 31 and the OPB pixel region 32. The effective non-matter pixel region 33 is a region in which the effective non-matter pixels 33 whose read pixel signals are not used to generate an image are arranged. The effective non-matter pixel 33 mainly plays a role of ensuring uniformity of the characteristics of the pixel signal of the normal pixel 31.

The present technology described below can be applied to both the pixel array units 3 illustrated in A of FIG. 2 and B of FIG. 2. Furthermore, the present technology described below can be applied to an arrangement other than the arrangement of the pixel array units 3 illustrated in A of FIG. 2 and B of FIG. 2.

For example, although the example in which the OPB pixel region 32 is formed on one side of the normal pixel 31 has been described, the OPB pixel region 32 may be provided on 2 to 4 sides. Furthermore, although the example in which the effective non-matter pixels 33 are also formed on one side of the normal pixel 31 has been described, the effective non-matter pixels 33 may be provided on 2 to 4 sides.

### Color Arrangement Example of Pixel Array Unit 3

The normal pixels 31 arranged in the normal pixel region 31 can be pixels that receive light in a visible light region, pixels that receive infrared light (IR), or the like. Furthermore, the normal pixel 31 can also be a pixel used for distance measurement.

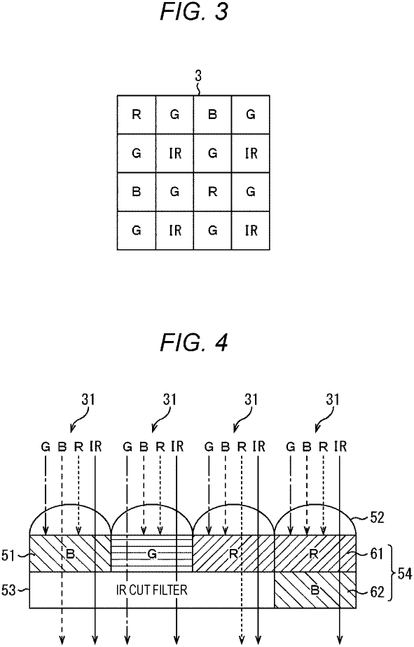

Referring to FIG. 3, a case where a pixel that receives light in a visible light region and a pixel that receives infrared light are arranged in the pixel array unit 3 will be described as an example. By arranging pixels that receive light in the visible light region and pixels that receive infrared light in the pixel array unit 3, a color image and an infrared image can be simultaneously acquired.

In a case where a pixel that receives light in the visible light region and a pixel that receives infrared light are arranged in the pixel array unit 3, as illustrated in FIG. 3, each of a red (R) pixel used for detection of red, a green (G) pixel used for detection of green, a blue (B) pixel used for detection of blue, and an IR pixel used for detection of infrared light is provided in a two-dimensional lattice shape in the pixel array unit 3.

FIG. 3 illustrates an example of arrangement of the normal pixels 31 of the pixel array unit 3. The example illustrated in FIG. 3 illustrates an example of a pixel array in which a pattern including 4 vertical pixels × 4 horizontal pixels is set as one unit, and the normal pixels 31 are arranged at a ratio of R pixels: G pixels: B pixels: IR pixels = 2: 8: 2: 4. More specifically, the G pixels are arranged in a checkered pattern. The R pixels are arranged in the first column of the first row and the third column of the third row. The B pixels are arranged in the third column of the first row and the first column of the third row. The IR pixels are arranged at the remaining pixel positions. Then, the pattern of the pixel array is repeatedly arranged in the row direction and the column direction on the pixel array unit 3.

The arrangement of the pixels illustrated in FIG. 3 is an example, and other arrangements can be used.

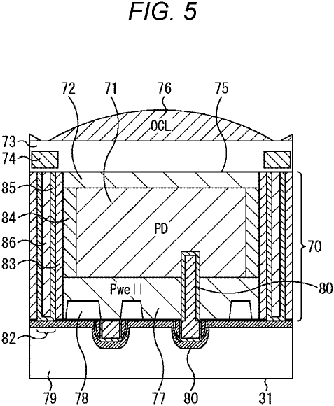

FIG. 4 schematically illustrates a configuration example of a filter of each normal pixel 31. In this example, a B pixel, a G pixel, an R pixel, and an IR pixel are arranged from left to right. In the R pixel, the G pixel, and the B pixel, an on-chip lens 52, a color filter layer 51, and an IR cut filter 53 are stacked in this order from the light incident side.

In the color filter layer 51, an R filter that transmits wavelength regions of red and infrared light is provided for the R pixel, a G filter that transmits wavelength regions of green and infrared light is provided for the G pixel, and a B filter that transmits wavelength regions of blue and infrared light is provided for the B pixel. The IR cut filter 53 is a filter having a transmission band for near-infrared light in a predetermined range.

In the IR pixel, an on-chip lens 52 and an IR filter 54 are stacked in this order from the light incident side. The IR filter 54 is formed by stacking an R filter 61 and a B filter 62. By stacking the R filter 61 and the B filter 62, the IR filter 54 (that is, blue + red) that transmits a light beam having a wavelength longer than 800 nm is formed.

In the IR filter 54 illustrated in FIG. 4, the R filter 61 is arranged on the on-chip lens 52 side, and the B filter 62 is arranged on the lower side thereof. However, the B filter 62 may be arranged on the on-chip lens 52 side, and the R filter 61 may be arranged on the lower side thereof.

In the normal pixel region 31, as described with reference to FIGS. 3 and 4, pixels that receive light in the visible light region and pixels that receive infrared light can be arranged. Alternatively, only pixels that receive light in the visible light region may be arranged in the normal pixel region 31. Furthermore, the present technology can also be applied to a case of a configuration in which only pixels that receive infrared light are arranged in the normal pixel region 31.

### Structure of Unit Pixel

Next, a specific structure of the normal pixels 31 arranged in a matrix in the normal pixel region 31 will be described. FIG. 5 is a vertical cross-sectional view of the normal pixel 31.

A case where the normal pixel 31 described below is a back-illuminated type will be described as an example, but the present technology can also be applied to a front-illuminated type.

The normal pixel 31 illustrated in FIG. 5 includes a photodiode (PD) 71 which is a photoelectric conversion element of each pixel formed inside a Si substrate 70. A P-type region 72 is formed on the light incident side (in the drawing, on the upper side and on the back surface side) of the PD 71, and a flattening film 73 is formed further below the P-type region 72. A boundary between the P-type region 72 and the flattening film 73 is defined as a backside Si interface 75.

A light shielding film 74 is formed on the flattening film 73. The light shielding film 74 is provided to prevent light from leaking into an adjacent pixel, and is formed between the adjacent PDs 71. The light shielding film 74 includes, for example, a metal material such as tungsten (W).

An on-chip lens (OCL) 76 that condenses incident light on the PD 71 is formed on the flattening film 73 and on the back surface side of the Si substrate 70.

Although not illustrated in FIG. 5, a cover glass or a transparent plate such as resin may be bonded onto the OCL 76. Furthermore, although not illustrated in FIG. 5, a color filter layer may be formed between the OCL 76 and the flattening film 73. Furthermore, the color filter layer can be the color filter layer 51 as illustrated in FIG. 4.

An active region (Pwell) 77 is formed on the opposite side (in the drawing, on the upper side and on the front surface side) of the light incident side of the PD 71. In the active region 77, element isolation regions (hereinafter, referred to as shallow trench isolation (STI)) 78 that isolate pixel transistors and the like are formed.

A wiring layer 79 is formed on the front surface side (upper side in the drawing) of the Si substrate 70 and on the active region 77, and a plurality of transistors is formed in the wiring layer 79. FIG. 5 illustrates an example in which a transfer transistor 80 is formed. The transfer transistor (gate) 80 includes a vertical transistor. That is, in the transfer transistor (gate) 80, a vertical transistor trench 81 is opened, and a transfer gate (TG) 80 for reading out charges from the PD 71 is formed therein.

Furthermore, pixel transistors such as an amplifier (AMP) transistor, a selection (SEL) transistor, and a reset (RST) transistor are formed on the front surface side of the Si substrate 70.

A trench is formed between the normal pixels 31. This trench is referred to as a deep trench isolation (DTI) 82. The DTI 82 is formed between the adjacent normal pixels 31 in a shape penetrating the Si substrate 70 in the depth direction (longitudinal direction in the drawing, and direction from front surface to back surface). Furthermore, the DTI 82 also functions as a light-shielding wall between pixels so that unnecessary light does not leak to the adjacent normal pixels 31.

A P-type solid-phase diffusion layer 83 and an N-type solid-phase diffusion layer 84 are formed between the PD 71 and the DTI 82 in order from the DTI 82 side toward the PD 71. The P-type solid-phase diffusion layer 83 is formed along the DTI 82 until it contacts the backside Si interface 75 of the Si substrate 70. The N-type solid-phase diffusion layer 84 is formed along the DTI 82 until it contacts the P-type region 72 of the Si substrate 70.

The P-type solid-phase diffusion layer 83 is formed until being in contact with the backside Si interface 75, but the N-type solid-phase diffusion layer 84 is not in contact with the backside Si interface 75, and a gap is provided between the N-type solid-phase diffusion layer 84 and the backside Si interface 75.

With such a configuration, the PN junction region of the P-type solid-phase diffusion layer 83 and the N-type solid-phase diffusion layer 84 forms a strong electric field region, and holds the charge generated by the PD 71. According to such a configuration, the P-type solid-phase diffusion layer 83 and the N-type solid-phase diffusion layer 84 formed along the DTI 82 form a strong electric field region, and can hold the charge generated in the PD 71.

With such a configuration, the N-type solid-phase diffusion layer 84 is not in contact with the backside Si interface 75 of the Si substrate 70, and is formed in contact with the P-type region 72 of the Si substrate 70 along the DTI 82. With such a configuration, it is possible to prevent pinning of electric charges from weakening, and it is possible to prevent electric charges from flowing into the PD 71 to deteriorate dark characteristics.

Furthermore, in the normal pixel 31 illustrated in FIG. 5, a sidewall film 85 including SiO2 is formed on the inner wall of the DTI 82, and a filler 86 including polysilicon is embedded inside the sidewall film.

### Structure of Unit Pixel

Next, another specific structure of the normal pixels 31 arranged in a matrix in the normal pixel region 31 will be described. In the normal pixel region 31, for example, a pixel that receives infrared light can be arranged, and a pixel for measuring a distance to a subject using a signal obtained from the pixel can be arranged. The cross-sectional configuration of the normal pixel 31 arranged in such a device (distance measuring device) that performs distance measurement will be described.

Furthermore, as a method of distance measurement, a distance pixel for performing distance measurement by a time-of-flight (ToF) method will be described as an example. In addition, the ToF method includes a Direct ToF (dToF) method and an Indirect ToF (iToF) method. First, a case where a pixel that performs distance measurement by the dToF method is arranged as the normal pixel 31 will be described as an example. The DToF method is a method of directly measuring the distance from the time when the subject is irradiated with light and the time when the reflected light reflected from the subject is received.

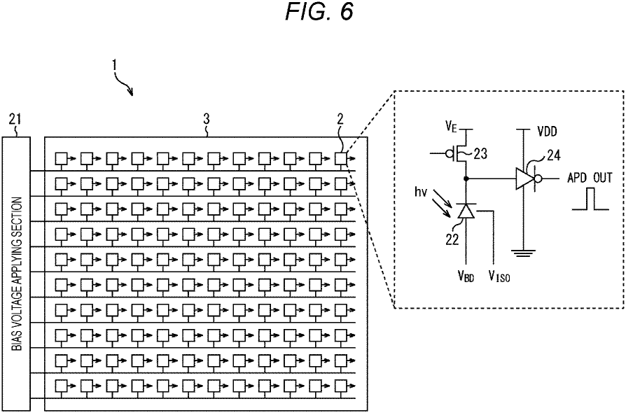

FIG. 6 is a diagram illustrating a configuration of the imaging device 1 when the normal pixels 31 are configured by pixels of the DToF method. In FIG. 6, the imaging device 1 includes a pixel array unit 3 and a bias voltage applying section 21.

The pixel array unit 3 is a light receiving surface that receives light condensed by an optical system (not illustrated), and a plurality of SPAD pixels 2 is arranged in a matrix. As illustrated on the right side of FIG. 6, the SPAD pixel 2 includes a SPAD element 22, a p-type Metal-Oxide-Semiconductor Field-Effect Transistor (MOSFET) 23, and a CMOS inverter 24.

The SPAD element 22 can form an avalanche multiplication region by applying a large negative voltage VBD to the cathode, and can avalanche multiply electrons generated by incidence of one photon. When the voltage by the electrons avalanche multiplied by the SPAD element 22 reaches the negative voltage VBD, the p-type MOSFET 23 emits the electrons multiplied by the SPAD element 22 and performs quenting to return to the initial voltage. The CMOS inverter 24 shapes the voltage generated by the electrons multiplied by the SPAD element 22 to output a light receiving signal (APD OUT) in which a pulse waveform is generated with the arrival time of one photon as a starting point.

The bias voltage applying section 21 applies a bias voltage to each of the plurality of SPAD pixels 2 arranged in the pixel array unit 3.

The imaging device 1 configured as described above outputs a light receiving signal for each SPAD pixel 2, and supplies the light receiving signal to an arithmetic processing section (not illustrated) in a subsequent stage. For example, the arithmetic processing section performs arithmetic processing of obtaining the distance to the subject on the basis of the timing at which a pulse indicating the arrival time of one photon is generated in each light receiving signal, and obtains the distance for each SPAD pixel 2. Then, on the basis of the distances, a distance image in which the distances to the subject detected by the plurality of SPAD pixels 2 are planarly arranged is generated.

### Configuration Example of SPAD Pixel

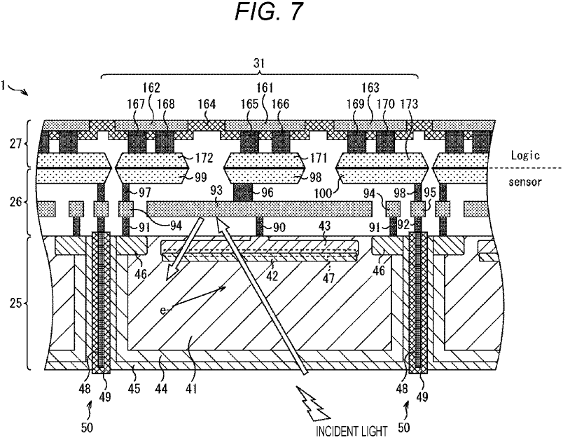

A configuration example of the SPAD pixel 2 formed in the imaging device 1 will be described with reference to FIG. 7. FIG. 7 is a diagram illustrating a cross-sectional configuration example of the SPAD pixel 2.

As illustrated in FIG. 7, the imaging device 1 has a stacked structure in which a sensor substrate 25, a sensor-side wiring layer 26, and a logic-side wiring layer 27 are stacked, and a logic circuit substrate (not illustrated) is stacked on the logic-side wiring layer 27. On the logic circuit substrate, for example, the bias voltage applying section 21, the p-type MOSFET 23, the CMOS inverter 24, and the like in FIG. 6 are formed. For example, the imaging device 1 can be manufactured by a manufacturing method in which the sensor-side wiring layer 26 is formed on the sensor substrate 25, the logic-side wiring layer 27 is formed on the logic circuit substrate, and then the sensor-side wiring layer 26 and the logic-side wiring layer 27 are joined together at a joining surface (a surface indicated by a broken line in FIG. 7).

The sensor substrate 25 is, for example, a semiconductor substrate obtained by thinly slicing single crystal silicon, and a p-type or n-type impurity concentration is controlled, and the SPAD element 22 is formed for each SPAD pixel 2. In addition, in FIG. 7, a surface facing the lower side of the sensor substrate 25 is a light receiving surface that receives light, and the sensor-side wiring layer 26 is stacked on a surface opposite to the light receiving surface.

In the sensor-side wiring layer 26 and the logic-side wiring layer 27, wiring for supplying a voltage to be applied to the SPAD element 22, wiring for extracting electrons generated in the SPAD element 22 from the sensor substrate 25, and the like are formed.

The SPAD element 22 includes an N-well 41, a P-type diffusion layer 42, an N-type diffusion layer 43, a hole accumulation layer 44, a pinning layer 45, and a high-concentration P-type diffusion layer 46 formed in the sensor substrate 25. Then, in the SPAD element 22, the avalanche multiplication region 47 is formed by a depletion layer formed in a region where the P-type diffusion layer 42 and the N-type diffusion layer 43 are connected.

The N-well 41 is formed by controlling the impurity concentration of the sensor substrate 25 to n-type, and forms an electric field that transfers electrons generated by photoelectric conversion in the SPAD element 22 to the avalanche multiplication region 47. Note that, instead of the N-well 41, a P-well may be formed by controlling the impurity concentration of the sensor substrate 25 to p-type.

The P-type diffusion layer 42 is a dense P-type diffusion layer (P+) formed in the vicinity of the front surface of the sensor substrate 25 and on the back surface side (lower side in FIG. 7) with respect to the N-type diffusion layer 43, and is formed over substantially the entire surface of the SPAD element 22.

The N-type diffusion layer 43 is a dense N-type diffusion layer (N+) formed in the vicinity of the surface of the sensor substrate 25 and on the front surface side (upper side in FIG. 7) with respect to the P-type diffusion layer 42, and is formed over substantially the entire surface of the SPAD element 22. In addition, the N-type diffusion layer 43 has a convex shape in which a part thereof is formed up to the front surface of the sensor substrate 25 in order to be connected to a contact electrode 90 for supplying a negative voltage for forming the avalanche multiplication region 47.

The hole accumulation layer 44 is a P-type diffusion layer (P) formed so as to surround the side surface and the bottom surface of the N-well 41, and accumulates holes. In addition, the hole accumulation layer 44 is electrically connected to the anode of the SPAD element 22 and enables bias adjustment. As a result, the hole concentration of the hole accumulation layer 44 is enhanced, and pinning including the pinning layer 45 is strengthened, so that, for example, generation of dark current can be suppressed.

The pinning layer 45 is a dense P-type diffusion layer (P+) formed on the front surface outside the hole accumulation layer 44 (the back surface of the sensor substrate 25 or the side surface in contact with an insulating film 49), and suppresses generation of dark current, for example, similarly to the hole accumulation layer 44.

The high-concentration P-type diffusion layer 46 is a dense P-type diffusion layer (P++) formed so as to surround the outer periphery of the N-well 41 in the vicinity of the front surface of the sensor substrate 25, and is used for connection with a contact electrode 91 for electrically connecting the hole accumulation layer 44 to the anode of the SPAD element 22.

The avalanche multiplication region 47 is a high electric field region formed at the boundary surface between the P-type diffusion layer 42 and the N-type diffusion layer 43 by a large negative voltage applied to the N-type diffusion layer 43, and multiplies electrons (e-) generated by one photon incident on the SPAD element 22.

Furthermore, in the imaging device 1, each SPAD element 22 is insulated and separated by an inter-pixel separation portion 50 having a double structure including a metal film 48 and the insulating film 49 formed between the adjacent SPAD elements 22. For example, the inter-pixel separation portion 50 is formed so as to penetrate from the back surface to the front surface of the sensor substrate 25.

The metal film 48 is a film including a metal (for example, tungsten or the like) that reflects light, and the insulating film 49 is a film having an insulating property such as SiO2. For example, the inter-pixel separation portion 50 is formed by being embedded in the sensor substrate 25 so that the front surface of the metal film 48 is covered with the insulating film 49, and the adjacent SPAD elements 22 are electrically and optically separated from each other by the inter-pixel separation portion 50.

In the sensor-side wiring layer 26, contact electrodes 90 to 92, metal wirings 93 to 95, contact electrodes 96 to 98, and metal pads 99 to 100 are formed.

The contact electrode 90 connects the N-type diffusion layer 43 and the metal wiring 93, the contact electrode 91 connects the high-concentration P-type diffusion layer 46 and the metal wiring 94, and the contact electrode 92 connects the metal film 48 and the metal wiring 95.

For example, as illustrated in FIG. 3, the metal wiring 93 is formed to be wider than the avalanche multiplication region 47 so as to cover at least the avalanche multiplication region 47. Then, the metal wiring 93 reflects the light transmitted through the SPAD element 22 to the SPAD element 22 as indicated by a white arrow in FIG. 7.

The metal wiring 94 is formed so as to overlap the high-concentration P-type diffusion layer 46 so as to surround the outer periphery of the metal wiring 93 in plan view. The metal wiring 95 is formed so as to be connected to the metal film 48 at four corners of the SPAD pixel 2 in plan view.

The contact electrode 96 connects the metal wiring 93 and the metal pad 99, a contact electrode 167 connects the metal wiring 94 and the metal pad 99, and a contact electrode 168 connects the metal wiring 95 and a metal pad 100.

The metal pads 99 to 82 are used to be electrically and mechanically bonded to metal pads 171 to 173 formed in the logic-side wiring layer 27 by the metals (Cu) forming the metal pads.

Electrode pads 161 to 163, an insulating layer 164, contact electrodes 165 to 170, and metal pads 171 to 173 are formed in the logic-side wiring layer 27.

Each of the electrode pads 161 to 163 is used for connection with a logic circuit substrate (not illustrated), and the insulating layer 164 insulates the electrode pads 161 to 163 from each other.

The contact electrodes 165 and 166 connect the electrode pad 161 and the metal pad 171, the contact electrodes 167 and 168 connect the electrode pad 162 and the metal pad 172, and the contact electrodes 169 and 170 connect the electrode pad 163 and the metal pad 173.

The metal pad 171 is bonded to the metal pad 99, the metal pad 172 is bonded to the metal pad 99, and the metal pad 173 is bonded to the metal pad 100.

With such a wiring structure, for example, the electrode pad 161 is connected to the N-type diffusion layer 43 via the contact electrodes 165 and 166, the metal pad 171, the metal pad 99, the contact electrode 96, the metal wiring 93, and the contact electrode 90. Therefore, in the SPAD pixel 2, a large negative voltage applied to the N-type diffusion layer 43 can be supplied from the logic circuit substrate to the electrode pad 161.

Furthermore, the electrode pad 162 is configured to be connected to the high-concentration P-type diffusion layer 46 via the contact electrodes 167 and 168, the metal pad 172, the metal pad 99, the contact electrode 97, the metal wiring 94, and the contact electrode 91. Therefore, in the SPAD pixel 2, the anode of the SPAD element 22 electrically connected to the hole accumulation layer 44 is connected to the electrode pad 162, so that bias adjustment to the hole accumulation layer 44 can be performed via the electrode pad 162.

Further, the electrode pad 163 is configured to be connected to the metal film 48 via the contact electrodes 169 and 170, the metal pad 173, the metal pad 100, the contact electrode 98, the metal wiring 95, and the contact electrode 92. Therefore, in the SPAD pixel 2, the bias voltage supplied from the logic circuit substrate to the electrode pad 163 can be applied to the metal film 48.

Then, as described above, in the SPAD pixel 2, the metal wiring 93 is formed to be wider than the avalanche multiplication region 47 so as to cover at least the avalanche multiplication region 47, and the metal film 48 is formed to penetrate the sensor substrate 25. That is, the SPAD pixel 2 is formed so as to have a reflection structure in which the entire SPAD element 22 except for the light incident surface is surrounded by the metal wiring 93 and the metal film 48. As a result, the SPAD pixel 2 can prevent the occurrence of optical crosstalk and improve the sensitivity of the SPAD element 22 by the effect of reflecting light by the metal wiring 93 and the metal film 48.

Furthermore, the SPAD pixel 2 can enable bias adjustment by a connection configuration in which the side surface and the bottom surface of the N well 41 are surrounded by the hole accumulation layer 44, and the hole accumulation layer 44 is electrically connected to the anode of the SPAD element 22. Furthermore, the SPAD pixel 2 can form an electric field that assists carriers in the avalanche multiplication region 47 by applying a bias voltage to the metal film 48 of the inter-pixel separation portion 50.

In the SPAD pixel 2 configured as described above, the occurrence of crosstalk is prevented, and the sensitivity of the SPAD element 22 is improved, so that the characteristics can be improved. Furthermore, such a SPAD pixel 2 can be used as the normal pixel 31.

### Another Cross-Sectional Configuration Example of Pixel

Next, another cross-sectional configuration of the normal pixel 31 arranged in a device (distance measuring device) that performs distance measurement will be described. The normal pixel 31 described below can be used as a distance measuring pixel of the iToF method.

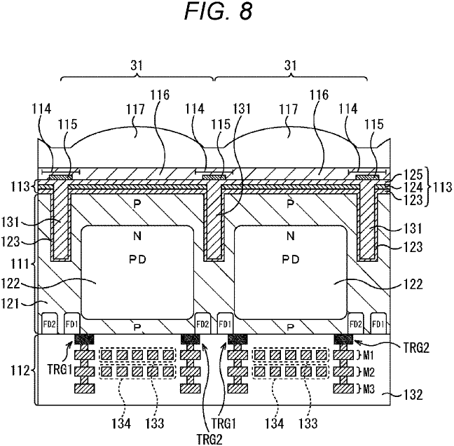

FIG. 8 is a cross-sectional view illustrating a configuration example of the normal pixel 31 arranged in the pixel array unit 3. The normal pixel 31 includes a semiconductor substrate 111 and a multilayer wiring layer 112 formed on a front surface side (lower side in the drawing) thereof.

The semiconductor substrate 111 includes, for example, silicon (Si), and is formed to have a thickness of, for example, 1 to 10 µm. In addition to silicon, a substrate including a material such as iridium gallium arsenide (InGaAs) may be used. In the semiconductor substrate 111, for example, an N-type (second conductivity type) semiconductor region 122 is formed in a P-type (first conductivity type) semiconductor region 121 in units of pixels, so that photodiodes PD are formed in units of pixels. The P-type semiconductor region 121 provided on both the front and back surfaces of the semiconductor substrate 111 also serves as a hole charge accumulation region for dark current suppression.

The upper surface of the semiconductor substrate 111 on the upper side in FIG. 8 is the back surface of the semiconductor substrate 111 and is the light incident surface on which light is incident. An antireflection film 113 is formed on the upper surface on the back surface side of the semiconductor substrate 111.

The antireflection film 113 has, for example, a stacked structure in which a fixed charge film and an oxide film are stacked, and for example, an insulating thin film having a high dielectric constant (High-k) by an atomic layer deposition (ALD) method can be used. Specifically, hafnium oxide (HfO2), aluminum oxide (Al2O3), titanium oxide (TiO2), strontium titan oxide (STO), or the like can be used. In the example of FIG. 8, the antireflection film 113 is formed by stacking a hafnium oxide film 123, an aluminum oxide film 124, and a silicon oxide film 125.

An inter-pixel light shielding film 115 that prevents incident light from entering an adjacent pixel is formed on the upper surface of the antireflection film 113 and at a boundary portion 114 (hereinafter, also referred to as a pixel boundary portion 114) between the adjacent normal pixels 31 of the semiconductor substrate 111. The material of the inter-pixel light shielding film 115 only needs to be a material that shields light, and for example, a metal material such as tungsten (W), aluminum (Al), or copper (Cu) can be used.

On the upper surface of the antireflection film 113 and the upper surface of the inter-pixel light shielding film 115, a flattening film 116 is formed by, for example, an insulating film such as silicon oxide (SiO2), silicon nitride (SiN), or silicon oxynitride (SiON), or an organic material such as resin.

Then, on the upper surface of the flattening film 116, an on-chip lens 117 is formed for each pixel. The on-chip lens 117 includes, for example, a resin material such as a styrene resin, an acrylic resin, a styrene-acrylic copolymer resin, or a siloxane resin. The light condensed by the on-chip lens 117 is efficiently incident on the photodiode PD.

Furthermore, at the pixel boundary portion 114 on the back surface side of the semiconductor substrate 111, an inter-pixel separation portion 131 that separates adjacent pixels in the depth direction of the semiconductor substrate 111 from each other from the back surface side (on-chip lens 117 side) of the semiconductor substrate 111 to a predetermined depth in the substrate depth direction is formed. An outer peripheral portion including a bottom surface and a side wall of the inter-pixel separation portion 131 is covered with the hafnium oxide film 123 which is a part of the antireflection film 113. The inter-pixel separation portion 131 prevents incident light from penetrating the adjacent normal pixel 31, confines the incident light in the own pixel, and prevents leakage of incident light from the adjacent normal pixel 31.

In the example of FIG. 8, since the silicon oxide film 125, which is the material of the uppermost layer of the antireflection film 113, is embedded in a trench (groove) dug from the back surface side to simultaneously form the silicon oxide film 125 and the inter-pixel separation portion 131, the silicon oxide film 125, which is a part of the stacked film as the antireflection film 113, and the inter-pixel separation portion 131 include the same material, but are not necessarily the same. The material to be buried in the trench (groove) dug from the back surface side as the inter-pixel separation portion 131 may be, for example, a metal material such as tungsten (W), aluminum (Al), titanium (Ti), or titanium nitride (TiN).

On the other hand, on the front surface side of the semiconductor substrate 111 on which the multilayer wiring layer 112 is formed, two transfer transistors TRG1 and TRG2 are formed for one photodiode PD formed in each normal pixel 31. Furthermore, on the front surface side of the semiconductor substrate 111, floating diffusion regions FD1 and FD2 as charge storage portions that temporarily hold the charges transferred from the photodiode PD are formed by high-concentration N-type semiconductor region (N-type diffusion region).

The multilayer wiring layer 112 includes a plurality of metal films M and an interlayer insulating film 132 therebetween. FIG. 8 illustrates an example including three layers of a first metal film M1 to a third metal film M3.

Among the plurality of metal films M of the multilayer wiring layer 112, for example, a wiring 133 is formed for the first metal film M1 and a wiring 134 is formed for the second metal film M2, the metal film M1, M2 being a predetermined metal film M.

As described above, the imaging device 1 has a back surface irradiation type structure in which the semiconductor substrate 111 that is a semiconductor layer is arranged between the on-chip lens 117 and the multilayer wiring layer 112, and incident light is made incident on the photodiode PD from the back surface side on which the on-chip lens 117 is formed.

Furthermore, the normal pixel 31 includes two transfer transistors TRG1 and TRG2 for the photodiode PD provided in each pixel, and is configured to be able to distribute charges (electrons) generated by photoelectric conversion by the photodiode PD to the floating diffusion region FD1 or FD2.

Here, a pixel used for distance measurement including two transfer transistors TRG1 and TRG2, which may be referred to as a two-tap type, will be described as an example.

The configuration of a pixel used for distance measurement is not limited to such a 2-tap type, and the pixel may be a pixel sometimes referred to as a 1-tap type including one transfer transistor. In the case of the 1-tap type, the configuration may be a configuration like the normal pixel 31 illustrated in FIG. 5. That is, the normal pixel 31 having the configuration illustrated in FIG. 5 can also be used as a pixel for performing distance measurement.

Furthermore, the configuration of the pixel used for distance measurement may be a configuration of a pixel that is sometimes referred to as a 4-tap type including four transfer transistors. The present technology is not limited to the number of transfer transistors included in one pixel, a distance measuring method, and the like, and can be applied.

Hereinafter, the description will be continued using the 2-tap type normal pixel 31 as an example. In the normal pixel 31 illustrated in FIG. 8, by forming the inter-pixel separation portion 131 in the pixel boundary portion 114, incident light is prevented from penetrating into the adjacent normal pixel 31, confined in the own pixel, and leakage of incident light from the adjacent normal pixel 31 is prevented.

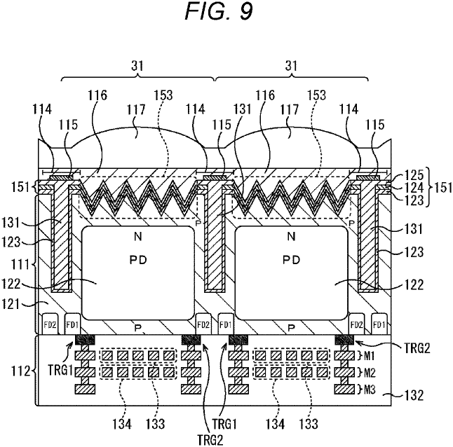

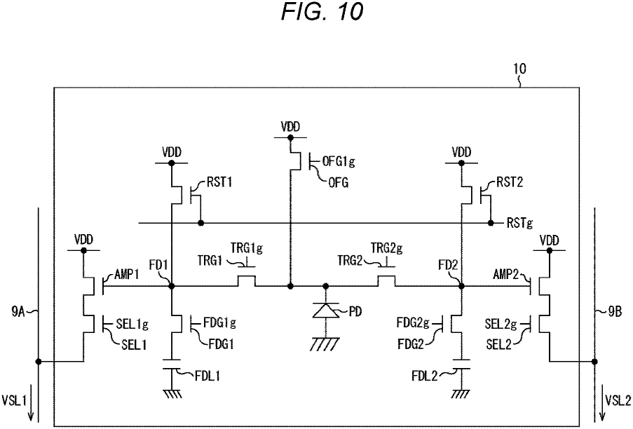

Another cross-sectional configuration of the normal pixel 31 used for distance measurement will be described with reference to FIG. 9.

In the normal pixel 31 illustrated in FIG. 9, a portion corresponding to that of the normal pixel 31 illustrated in FIG. 8 is denoted by the same reference numeral, and the description of the portion is appropriately omitted. In the normal pixel 31 illustrated in FIG. 9, a PD upper region 153 located above the formation region of the photodiode PD in (the P-type semiconductor region 121 of) the semiconductor substrate 111 has an uneven structure in which fine unevenness is formed. Furthermore, corresponding to the uneven structure of the PD upper region 153 of the semiconductor substrate 111, the antireflection film 151 formed on the upper surface thereof is also formed with the uneven structure. The antireflection film 151 is formed by stacking a hafnium oxide film 123, an aluminum oxide film 124, and a silicon oxide film 125.

As described above, by making the PD upper region 153 of the semiconductor region 121 have an uneven structure, it is possible to alleviate a rapid change in refractive index at the substrate interface and reduce the influence of reflected light.

Note that, in FIG. 9, the inter-pixel separation portion 131 including DTI formed by digging from the back surface side (on-chip lens 117 side) of the semiconductor region 121 is formed up to a position slightly deeper than the inter-pixel separation portion 131 in FIG. 8. The depth in the substrate thickness direction at which the inter-pixel separation portion 131 is formed can be set to any depth as described above.

### Circuit Configuration Example of Pixel

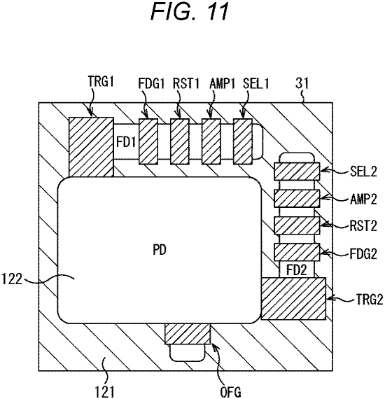

FIG. 10 illustrates a circuit configuration when the normal pixel 31 is two-dimensionally arranged in the pixel array unit 3 and the normal pixel 31 is an imaging element having a configuration suitable for performing distance measurement illustrated in FIGS. 8 or 9.

The normal pixel 31 includes a photodiode PD as a photoelectric conversion element. Furthermore, the normal pixel 31 includes two transfer transistors TRG, two floating diffusion regions FD, two additional capacitors FDL, two switching transistors FDG, two amplification transistors AMP, two reset transistors RST, and two selection transistors SEL. Furthermore, the normal pixel 31 includes a charge discharge transistor OFG.

Here, in a case where the transfer transistors TRG, the floating diffusion regions FD, the additional capacitances FDL, the switching transistors FDG, the amplification transistors AMP, the reset transistors RST, and the selection transistors SEL provided two by two in the normal pixel 31 are distinguished from one another, as illustrated in FIG. 10, they are respectively referred to as the transfer transistors TRG1 and TRG2, the floating diffusion regions FD1 and FD2, the additional capacitances FDL1 and FDL2, the switching transistors FDG1 and FDG2, the amplification transistors AMP1 and AMP2, the reset transistors RST1 and RST2, and the selection transistors SEL1 and SEL2.

The transfer transistor TRG, the switching transistor FDG, the amplification transistor AMP, the selection transistor SEL, the reset transistor RST, and the charge discharge transistor OFG are configured by, for example, N-type MOS transistors.

When a transfer drive signal TRGlg supplied to the gate electrode becomes an active state, the transfer transistor TRG1 becomes a conductive state in response thereto, thereby transferring the charge accumulated in the photodiode PD to the floating diffusion region FD1. When a transfer drive signal TRG2g supplied to the gate electrode becomes an active state, the transfer transistor TRG2 becomes a conductive state in response thereto, thereby transferring the charge accumulated in the photodiode PD to the floating diffusion region FD2.

The floating diffusion regions FD1 and FD2 are charge storage portions that temporarily hold the charge transferred from the photodiode PD.

When an FD drive signal FDGlg supplied to the gate electrode of the switching transistor FDG1 becomes an active state, the switching transistor FDG1 becomes a conductive state in response thereto, thereby connecting the additional capacitance FDL1 to the floating diffusion region FD1. When an FD drive signal FDG2g supplied to the gate electrode of the switching transistor FDG2 becomes an active state, the switching transistor FDG2 becomes a conductive state in response thereto, thereby connecting the additional capacitance FDL2 to the floating diffusion region FD2. The additional capacitances FDL1 and FDL2 are formed by the wiring 134 of FIG. 8.

When a reset drive signal RSTg supplied to the gate electrode of the reset transistor RST1 becomes an active state, the reset transistor RST1 becomes a conductive state, thereby resetting the potential of the floating diffusion region FD1. When a reset drive signal RSTg supplied to the gate electrode of the reset transistor RST2 becomes an active state, the reset transistor RST2 becomes a conductive state, thereby resetting the potential of the floating diffusion region FD2. Note that when the reset transistors RST1 and RST2 are activated, the switching transistors FDG1 and FDG2 are also activated at the same time, and the additional capacitances FDL1 and FDL2 are also reset.

For example, when the vertical drive circuit 4 is at high illuminance in which the amount of incident light is large, the vertical drive circuit 4 activates the switching transistors FDG1 and FDG2, connects the floating diffusion region FD1 and the additional capacitance FDL1, and connects the floating diffusion region FD2 and the additional capacitance FDL2. As a result, more electric charges can be accumulated at high illuminance.

On the other hand, when the vertical drive circuit 4 is at low illuminance in which the amount of incident light is small, the vertical drive circuit 4 inactivates the switching transistors FDG1 and FDG2, and separates the additional capacitances FDL1 and FDL2 from the floating diffusion regions FD1 and FD2, respectively. As a result, the conversion efficiency can be increased.

When a discharge drive signal OFG1g supplied to the gate electrode becomes an active state, the charge discharge transistor OFG becomes a conductive state in response thereto, thereby discharging the charge accumulated in the photodiode PD.

The source electrode of the amplification transistor AMP1 is connected to a vertical signal line 9A via the selection transistor SEL1, so that the amplification transistor AMP1 is connected to a constant current source (not illustrated) to constitute a source follower circuit. The source electrode of the amplification transistor AMP2 is connected to a vertical signal line 9B via the selection transistor SEL2, so that the amplification transistor AMP2 is connected to a constant current source (not illustrated) to constitute a source follower circuit.

The selection transistor SEL1 is connected between the source electrode of the amplification transistor AMP1 and the vertical signal line 9A. When the selection signal SEL1g supplied to the gate electrode becomes an active state, the selection transistor SEL1 becomes a conductive state in response thereto, and outputs a detection signal VSL1 output from the amplification transistor AMP1 to the vertical signal line 9A.

The selection transistor SEL2 is connected between the source electrode of the amplification transistor AMP2 and the vertical signal line 9B. When a selection signal SEL2g supplied to the gate electrode becomes an active state, the selection transistor SEL2 becomes a conductive state in response thereto, and outputs a detection signal VSL2 output from the amplification transistor AMP2 to the vertical signal line 9B.

The transfer transistors TRG1 and TRG2, the switching transistors FDG1 and FDG2, the amplification transistors AMP1 and AMP2, the selection transistors SEL1 and SEL2, and the charge discharge transistor OFG of the normal pixel 31 are controlled by the vertical drive circuit 4.

In the pixel circuit of FIG. 10, the additional capacitances FDL1 and FDL2 and the switching transistors FDG1 and FDG2 that control the connection thereof may be omitted, but a high dynamic range can be secured by providing the additional capacitance FDL and selectively using them in accordance with the amount of incident light.

The operation of the normal pixel 31 will be briefly described.

First, before light reception is started, a reset operation for resetting electric charges in the normal pixels 31 is performed in all the pixels. That is, the charge discharge transistor OFG, the reset transistors RST1 and RST2, and the switching transistors FDG1 and FDG2 are turned on, and the accumulated charges of the photodiode PD, the floating diffusion regions FD1 and FD2, and the additional capacitances FDL1 and FDL2 are discharged.

After the accumulated charges are discharged, light reception is started in all the pixels.

In a light receiving period, the transfer transistors TRG1 and TRG2 are alternately driven. That is, in a first period, the transfer transistor TRG1 is controlled to be on, and the transfer transistor TRG2 is controlled to be off. In the first period, the charge generated in the photodiode PD is transferred to the floating diffusion region FD1. In a second period next to the first period, the transfer transistor TRG1 is controlled to be off, and the transfer transistor TRG2 is controlled to be on. In the second period, the charge generated in the photodiode PD is transferred to the floating diffusion region FD2. As a result, the charge generated in the photodiode PD is distributed and accumulated in the floating diffusion regions FD1 and FD2.

Here, the transfer transistor TRG and the floating diffusion region FD on which the charge (electron) obtained by the photoelectric conversion is read are also referred to as active taps. Conversely, the transfer transistor TRG and the floating diffusion region FD on which reading of the charge obtained by photoelectric conversion is not performed are also referred to as inactive taps.

Then, when the light receiving period ends, each normal pixel 31 of the pixel array unit 3 is selected line by line. In the selected normal pixel 31, the selection transistors SEL1 and SEL2 are turned on. As a result, the charges accumulated in the floating diffusion region FD1 are output to the column signal processing circuit 5 via the vertical signal line 9A as the detection signal VSL1. The charges accumulated in the floating diffusion region FD2 are output as the detection signal VSL2 to the column signal processing circuit 5 via the vertical signal line 9B.

As described above, one light receiving operation ends, and the next light receiving operation starting from the reset operation is executed.

The reflected light received by the normal pixel 31 is delayed in accordance with the distance to an object from the timing at which the light source emits the light. Since the distribution ratio of the charges accumulated in the two floating diffusion regions FD1 and FD2 changes depending on the delay time in accordance with the distance to the object, the distance to the object can be obtained from the distribution ratio of the charges accumulated in the two floating diffusion regions FD1 and FD2.

### Plan View of Pixel

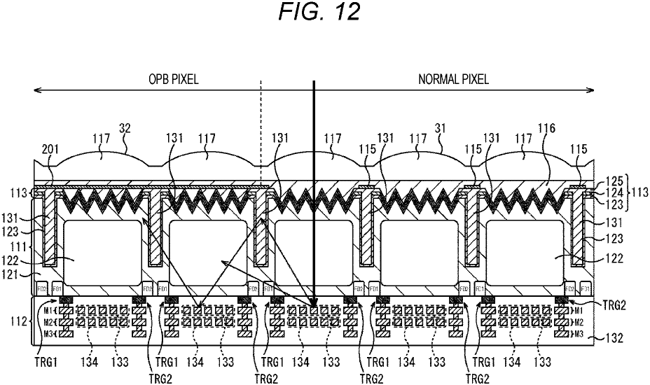

FIG. 11 is a plan view illustrating an arrangement example of the pixel circuit illustrated in FIG. 10. The horizontal direction in FIG. 10 corresponds to the row direction (horizontal direction) in FIG. 1, and the vertical direction corresponds to the column direction (vertical direction) in FIG. 1.

As illustrated in FIG. 11, a photodiode PD includes an N-type semiconductor region 122 in a central region of the rectangular normal pixel 31.

The transfer transistor TRG1, the switching transistor FDG1, the reset transistor RST1, the amplification transistor AMP1, and the selection transistor SEL1 are linearly arranged along a predetermined side of the four sides of the rectangular normal pixel 31 outside the photodiode PD, and the transfer transistor TRG2, the switching transistor FDG2, the reset transistor RST2, the amplification transistor AMP2, and the selection transistor SEL2 are linearly arranged along the other side of the four sides of the rectangular normal pixel 31.

Furthermore, the charge discharge transistor OFG is arranged on a side different from the two sides of the normal pixel 31 in which the transfer transistor TRG, the switching transistor FDG, the reset transistor RST, the amplification transistor AMP, and the selection transistor SEL are formed.

Note that the arrangement of the pixel circuit illustrated in FIG. 11 is not limited to this example, and other arrangements may be adopted.

### Influence of Reflected Light

As described with reference to FIG. 2, the normal pixel region 31 and the OPB pixel region 32 are arranged in the pixel array unit 3. While the normal pixel region 31 is opened, the OPB pixel region 32 is light-shielded.

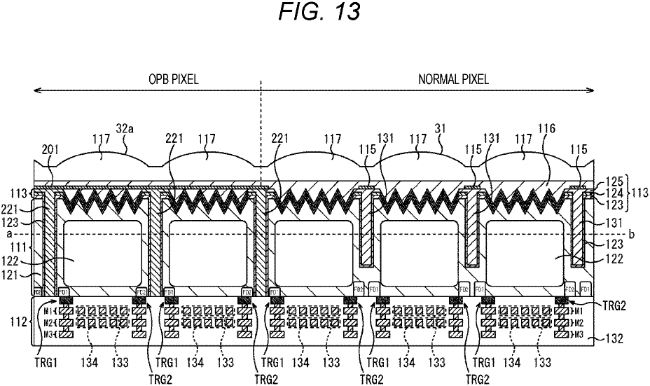

FIG. 12 illustrates a cross-sectional view of pixels in a region where the normal pixel region 31 and the OPB pixel region 32 are arranged adjacent to each other. FIG. 12 illustrates an example in which two OPB pixels 32 are arranged on the left side in the drawing and three normal pixels 31 are arranged on the right side. Furthermore, a case where the normal pixel 31 is the normal pixel 31 having the uneven structure illustrated in FIG. 9 is illustrated.

A basic configuration of the OPB pixel 32 can be the same as that of the normal pixel 31. Since the OPB pixel region 32 is light-shielded, a light shielding film 201 is formed on the on-chip lens 117 side of the OPB pixel 32, and incident light is shielded.

Note that the OPB pixel 32 and the effective non-matter pixel 33 can also be referred to as dummy pixels. The OPB pixel 32 and the effective non-matter pixel 33 are pixels whose read pixel signals are not used for generating an image. The fact that the read pixel signal is not used for generating an image can also be said to be a pixel that is not displayed on the reproduced screen.

Although the OPB pixel 32 illustrated in FIG. 12 has a configuration including the on-chip lens 117, the configuration of the OPB pixel 32 and the effective non-matter pixel 33 (dummy pixel) may not include the on-chip lens 117. Furthermore, it may be configured such that the on-chip lens 117 is formed in a state in which a light condensing function is deteriorated, such as being crushed.

Furthermore, the dummy pixels may not be connected by the vertical signal line 9 (FIG. 1) in plan view.

Furthermore, the dummy pixel may be configured not to include a transistor equivalent to the transistor included in the effective pixel (normal pixel 31). Although the transistors included in the normal pixel 31 have been described in FIGS. 10 and 11, the normal pixel 31 includes a plurality of transistors, but a pixel including fewer transistors than the plurality of transistors included in the normal pixel 31 can be a dummy pixel.

As described above, the dummy pixel has a configuration different from that of the normal pixel 31, and as illustrated in FIG. 12, the dummy pixel has the light shielding film 201, or at least one of the elements (transistors, FD, OCL, and the like) of the normal pixel 31 has a different configuration.

In the following description, the configuration of the OPB pixel 32 is basically similar to that of the normal pixel 31, but the description will be continued by exemplifying a case where the OPB pixel 32 has a configuration different from that of the normal pixel 31 in that the OPB pixel 32 has the light shielding film 201.

Furthermore, in the following description, a structure having an uneven structure in the PD upper region 153 as in the OPB pixel 32 illustrated in FIG. 12 will be described as an example, but the OPB pixel 32 may be configured not to have an uneven structure.

As indicated by an arrow in FIG. 12, light enters the normal pixel 31. The light incident on the normal pixel 31 reaches, for example, the wiring in the multilayer wiring layer 112, and there is also light reflected. The reflected light reaches the inter-pixel separation portion 131, is reflected, and some light is returned into the normal pixel 31, but some light is transmitted and leaks into the adjacent OPB pixel 32. In a case where the inter-pixel separation portion 131 includes only a trench, or the like, there is a possibility that among light beams reflected by the wiring in the multilayer wiring layer 112, the number of light beams passing through the inter-pixel separation portion 131 (trench) and leaking into the adjacent OPB pixel 32 increases.

Furthermore, among the light beams reflected by the wiring in the multilayer wiring layer 112, some light beams may leak into the adjacent OPB pixel 32 through the P-type semiconductor region 121 in which the inter-pixel separation portion 131 is not formed. Furthermore, there is a possibility that the light beam leaking into the OPB pixel 32 further leaks also into the adjacent OPB pixel 32.

In addition, some distance measurement pixels used for distance measurement are designed to receive long-wavelength light such as near-infrared light. The long-wavelength light tends to travel while being reflected in the silicon substrate because of low quantum efficiency in the silicon substrate. That is, in the case of long-wavelength light, there is a high possibility that the amount of light leaking into adjacent pixel increases as described above.

In a case of a pixel that handles long-wavelength light, there is a possibility that the amount of light leaking from the normal pixel 31 to the OPB pixel 32 increases.

Since the OPB pixel 32 is used to read a black level signal which is a pixel signal indicating a black level of an image, the OPB pixel 32 is configured to shield light and prevent light from entering. However, as described above, if there is leakage of light from the adjacent normal pixel 31 or OPB pixel 32 to the OPB pixel 32, floating of the black level occurs, or variation occurs for each OPB pixel 32, and there is a possibility that setting accuracy of the black level is degraded.

In the embodiment to which the present technology described below is applied, it is possible to reduce leakage of light into the OPB pixel 32 and to prevent deterioration in black level setting accuracy.

### First Embodiment

Hereinafter, an imaging element to which the present technology is applied capable of reducing leakage of light into the OPB pixel 32 will be described. In the following description, a case where the configuration of the imaging element is the configuration of the normal pixel 31 illustrated in FIG. 9 and the basic configuration of the OPB pixel 32 is also similar to the configuration of the normal pixel 31 illustrated in FIG. 9 will be described as an example.

The embodiment described below can also be applied to an imaging pixel that does not have the uneven structure as illustrated in FIG. 8. Furthermore, in the embodiment described below, an imaging element having a structure suitable for distance measurement illustrated in FIG. 9 will be described as an example, but the present technology can also be applied to pixels and the like that capture color images.

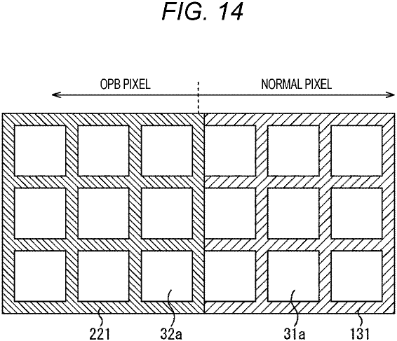

FIG. 13 is a diagram illustrating a cross-sectional configuration example of the imaging element in the first embodiment. The imaging element in the first embodiment illustrated in FIG. 13 is compared with the imaging element illustrated in FIG. 12. Since the imaging element in the first embodiment illustrated in FIG. 13 is similar to the imaging element illustrated in FIG. 12 except that an inter-pixel separation portion 221 of an OPB pixel 32a illustrated in FIG. 13 is different from the inter-pixel separation portion 131 of the OPB pixel 32 illustrated in FIG. 12, the description thereof is omitted.

The inter-pixel separation portion 221 of the OPB pixel 32a illustrated in FIG. 13 is configured to penetrate the semiconductor region 121 in the vertical direction in the drawing. The inter-pixel separation portion 131 of the normal pixel 31 is formed in a non-penetrating manner, whereas the inter-pixel separation portion 221 of the OPB pixel 32a is configured to penetrate therethrough.

As described above, the inter-pixel separation portion 131 of the normal pixel 31 and the inter-pixel separation portion 221 of the OPB pixel 32a arranged in the pixel array unit 3 have different configurations.

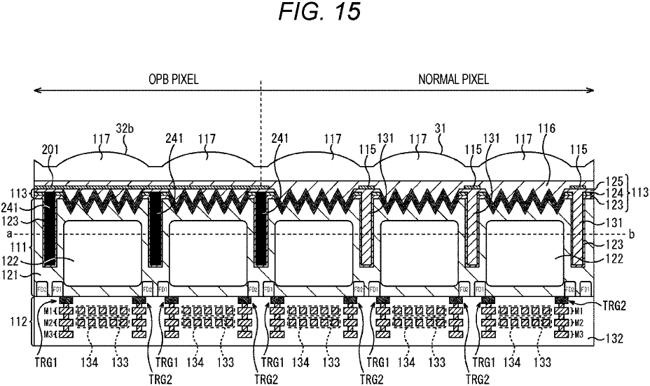

FIG. 14 is a plan view of the normal pixel 31 and the OPB pixel 32a on a line segment a-b in FIG. 13. In FIG. 14, one quadrangle represents the normal pixel 31 or the OPB 32a. One normal pixel 31 is surrounded by the inter-pixel separation portion 131 formed in a non-penetrating manner. In other words, in the normal pixel region 31, the inter-pixel separation portion 131 formed in a non-penetrating manner in a lattice shape is formed.

One OPB pixel 32a is surrounded by the inter-pixel separation portion 221 formed in a penetrating manner. In other words, in the OPB pixel region 32a, the inter-pixel separation portion 221 formed in a penetrating manner in a lattice shape is formed.

By configuring the inter-pixel separation portion 221 of the OPB pixel 32a in the first embodiment to penetrate the semiconductor region 121, light leaking from the normal pixel 31 can be suppressed.

For example, in the OPB pixel 32 described with reference to FIG. 12, there has been a possibility that the light enters the normal pixel 31, is reflected by the wiring of the multilayer wiring layer 112, passes through the semiconductor region 121 under the inter-pixel separation portion 131 formed in the OPB pixel 32 in FIG. 12, and enters the OPB pixel 32. In the OPB pixel 32a illustrated in FIG. 13, the inter-pixel separation portion 221 is also formed in the semiconductor region 121 under the inter-pixel separation portion 131 formed in the OPB pixel 32 in FIG. 12, and thus, it is possible to prevent reflected light that passes through this region and enters the OPB pixel 32a.

### Second Embodiment

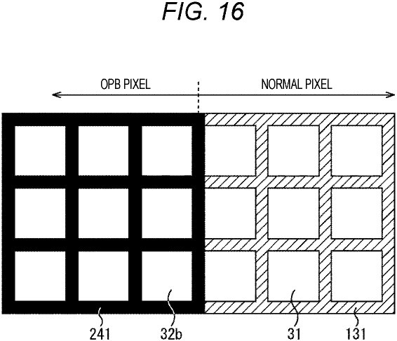

FIG. 15 is a diagram illustrating a cross-sectional configuration example of an imaging element according to the second embodiment. The imaging element in the second embodiment illustrated in FIG. 15 is compared with the imaging element illustrated in FIG. 12. Since the imaging element in the second embodiment illustrated in FIG. 15 is similar to the imaging element illustrated in FIG. 12 except that an inter-pixel separation portion 241 of an OPB pixel 32b illustrated in FIG. 15 is different from the inter-pixel separation portion 131 of the OPB pixel 32 illustrated in FIG. 12, the description thereof is omitted.

The inter-pixel separation portion 241 of the OPB pixel 32b illustrated in FIG. 15 is filled with a material that absorbs light. The material with which the inter-pixel separation portion 241 of the OPB pixel 32b is filled is different from the material with which the inter-pixel separation portion 131 of the normal pixel 31 is filled.

The inter-pixel separation portion 131 of the normal pixel 31 is filled with a material suitable for returning the incident light or the reflected light reflected by the wiring in the multilayer wiring layer 112 to the PD 52 and confining the light in the PD 52. In other words, the inter-pixel separation portion 131 of the normal pixel 31 is filled with a material (described as material A) having higher reflection performance than light shielding performance.

The inter-pixel separation portion 241 of the OPB pixel 32b is filled with a material suitable for suppressing leakage of light from the adjacent normal pixel 31 or OPB pixel 32b. In other words, the inter-pixel separation portion 241 of the OPB pixel 32b is filled with a material having higher light shielding performance than reflection performance or high light absorbing performance (described as material B).

The inter-pixel separation portion 241 of the OPB pixel 32b can be filled with a material having a high absorption coefficient of near-infrared light or a material having a high reflection coefficient. Furthermore, the inside of the inter-pixel separation portion 241 may be a single layer film or a multilayer film.

Examples of the material with which the inter-pixel separation portion 241 of the OPB pixel 32b is filled include SiO2 (silicon dioxide), Al (aluminum), W (tungsten), Cu (copper), Ti (titanium), TiN (titanium nitride), and Ta (tantalum).

As described above, the inter-pixel separation portion 131 of the normal pixel 31 and the inter-pixel separation portion 241 of the OPB pixel 32b arranged in the pixel array unit 3 have different configurations.

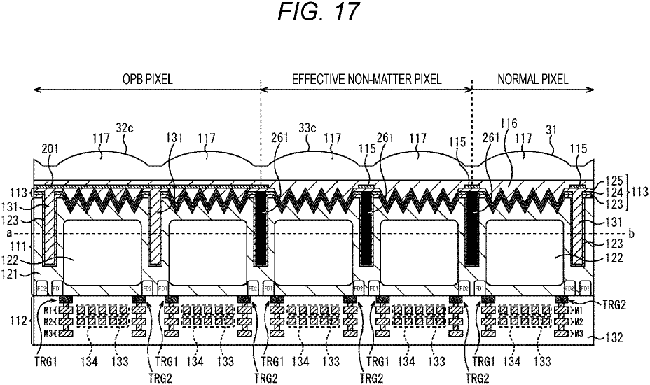

FIG. 16 is a plan view of the normal pixel 31 and the OPB pixel 32b on a line segment a-b in FIG. 15. In FIG. 16, one quadrangle represents the normal pixel 31 or the OPB 32b. One normal pixel 31 is surrounded by the inter-pixel separation portion 131 filled with the material A. In other words, the inter-pixel separation portion 131 filled with the material A in a lattice shape is formed in the normal pixel region 31.

One OPB pixel 32b is surrounded by the inter-pixel separation portion 241 filled with the material B. In other words, the inter-pixel separation portion 241 filled with the material B in a lattice shape is formed in the OPB pixel region 32b.

By configuring the inter-pixel separation portion 241 of the OPB pixel 32b in the second embodiment to be filled with the material B having a high light blocking property, it is possible to suppress light leaking from the normal pixel 31.

### Third Embodiment

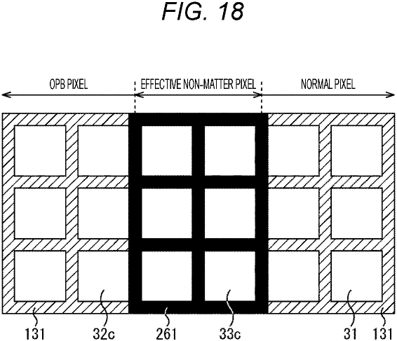

FIG. 17 is a diagram illustrating a cross-sectional configuration example of an imaging element according to the third embodiment. The imaging element according to the third embodiment is a case where the second embodiment is applied to a configuration in which the normal pixel region 31, the OPB pixel region 32, and the effective non-matter pixel region 33 are provided in the pixel array unit 3 as illustrated in B of FIG. 2.

The imaging element in the third embodiment illustrated in FIG. 17 is compared with the imaging element illustrated in FIG. 15. The same configuration as that of the inter-pixel separation portion 241 of the OPB pixel 32b illustrated in FIG. 15 is applied to an inter-pixel separation portion 261 of the effective non-matter pixel 33 illustrated in FIG. 17.

The inter-pixel separation portion 261 of the effective non-matter pixel 33c illustrated in FIG. 17 is filled with a material that absorbs light. The material with which the inter-pixel separation portion 261 of the effective non-matter pixel 33c is filled is different from the material with which the inter-pixel separation portion 131 of the normal pixel 31 is filled. The inter-pixel separation portion 261 of the effective non-matter pixel 33c is filled with a material suitable for suppressing leakage of light from the adjacent normal pixel 31 or effective non-matter pixel 33c.

The material with which the inter-pixel separation portion 261 of the effective non-matter pixel 33c illustrated in FIG. 17 is filled is different from the material with which the inter-pixel separation portion 131 of the OPB pixel 32c is filled.

In the example illustrated in FIG. 17, the basic configuration of the OPB pixel 32c is similar to the configuration of the normal pixel 31, but the basic configuration of the OPB pixel 32c may be similar to the configuration of the effective non-matter pixel 33c. That is, the inter-pixel separation portion 131 of the OPB pixel 32c can be configured to be filled with a material having a high light-shielding property, similarly to the inter-pixel separation portion 261 of the effective non-matter pixel region 33c.

Furthermore, the inter-pixel separation portion 131 of the OPB pixel 32c may have a structure different from that of the inter-pixel separation portion 261 of the effective non-matter pixel 33c and that of the inter-pixel separation portion 131 of the normal pixel 31.

Examples of the material with which the inter-pixel separation portion 261 of the effective non-matter pixel 33c is filled include SiO2 (silicon dioxide), Al (aluminum), W (tungsten), Cu (copper), Ti (titanium), TiN (titanium nitride), and Ta (tantalum).

As described above, the inter-pixel separation portion 131 of the normal pixel 31 and the inter-pixel separation portion 261 of the effective non-matter pixel 33c arranged in the pixel array unit 3 have different configurations.

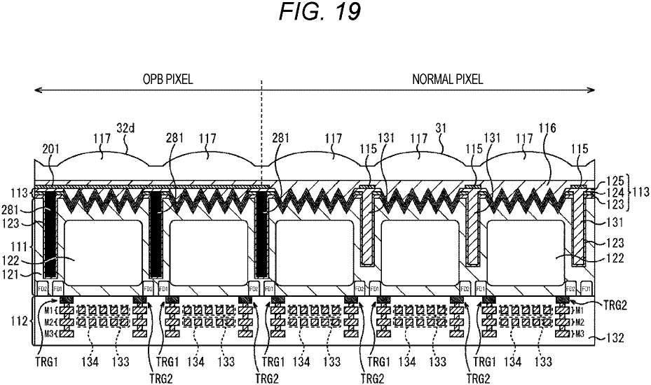

FIG. 18 is a plan view of the normal pixel 31, the OPB pixel 32c, and the effective non-matter pixel 33c in the line segment a-b in FIG. 17. In FIG. 18, one quadrangle represents the normal pixel 31, the OPB 32c, or the effective non-matter pixel 33c. One normal pixel 31 is surrounded by the inter-pixel separation portion 131 filled with the material A. In other words, the inter-pixel separation portion 131 filled with the material A in a lattice shape is formed in the normal pixel region 31.

In the example illustrated in FIG. 18, one OPB pixel 32c is surrounded by the inter-pixel separation portion 131 filled with the material A, similarly to one normal pixel 31. In other words, the inter-pixel separation portion 131 filled with the material A in a lattice shape is formed in the OPB pixel region 32c.

One effective non-matter pixel 33c is surrounded by the inter-pixel separation portion 261 filled with the material B. In other words, the inter-pixel separation portion 261 filled with the material B in a lattice shape is formed in the effective non-matter pixel region 33.

With the configuration in which the inter-pixel separation portion 261 of the effective non-matter pixel 33c in the third embodiment is filled with the material B having a high light shielding property, light leaking from the normal pixel 31 can be suppressed. Furthermore, since light leaking into the effective non-matter pixel 33c can be suppressed, light leaking into the OPB pixel 32c adjacent to the effective non-matter pixel 33c can also be suppressed.

### Fourth Embodiment

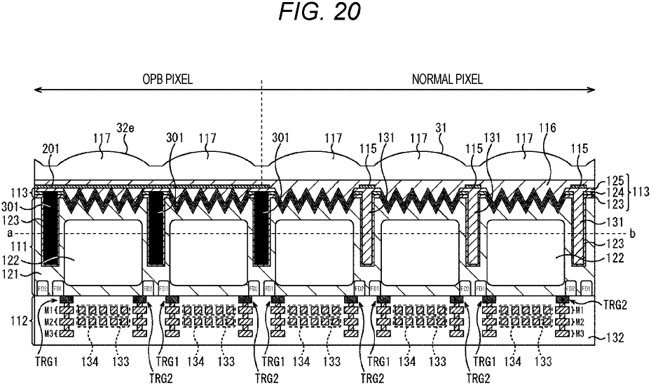

FIG. 19 is a diagram illustrating a cross-sectional configuration example of an imaging element according to the fourth embodiment. The imaging element in the fourth embodiment illustrated in FIG. 19 is compared with the imaging element illustrated in FIG. 15. Since the imaging element in the fourth embodiment illustrated in FIG. 19 is similar to the imaging element illustrated in FIG. 15 except that an inter-pixel separation portion 281 of an OPB pixel 32d illustrated in FIG. 19 is formed up to a position deeper than the inter-pixel separation portion 241 of the OPB pixel 32b illustrated in FIG. 15, the description thereof is omitted.

The inter-pixel separation portion 281 of the OPB pixel 32d in the fourth embodiment is formed up to a position deeper than the inter-pixel separation portion 131 of the normal pixel 31, and is filled with a material having a characteristic of absorbing light more than the inter-pixel separation portion 131.

The inter-pixel separation portion 281 of the OPB pixel 32d may have a configuration (penetrating trench) penetrating the semiconductor substrate 111 as in the inter-pixel separation portion 221 (FIG. 13) of the OPB pixel 32a in the first embodiment, and the inside of the trench may be filled with a material having a characteristic of absorbing light.

Also in the OPB pixel 32d according to the fourth embodiment, it is possible to suppress light leaking from the normal pixel 31 to the OPB pixel 32d and light leaking from the adjacent OPB pixel 32d.

### Fifth Embodiment

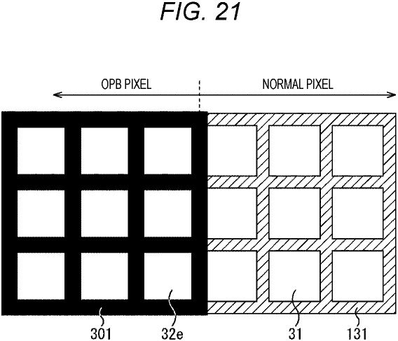

FIG. 20 is a diagram illustrating a cross-sectional configuration example of an imaging element according to the fifth embodiment. The imaging element in the fifth embodiment illustrated in FIG. 20 is compared with the imaging element illustrated in FIG. 15. Since the imaging element in the fifth embodiment illustrated in FIG. 20 is similar to the imaging element illustrated in FIG. 15 except that an inter-pixel separation portion 301 of an OPB pixel 32e illustrated in FIG. 20 is formed thicker than the inter-pixel separation portion 241 of the OPB pixel 32b illustrated in FIG. 15, the description thereof is omitted.

The inter-pixel separation portion 301 of the OPB pixel 32e in the fifth embodiment is formed thicker than the inter-pixel separation portion 131 of the normal pixel 31, and is filled with a material having a characteristic of absorbing light more than the inter-pixel separation portion 131.

The inter-pixel separation portion 301 of the OPB pixel 32e may have a configuration (penetrating trench) penetrating the semiconductor substrate 111 as in the inter-pixel separation portion 221 (FIG. 13) of the OPB pixel 32a in the first embodiment, and the inside of the trench may be filled with a material having a characteristic of absorbing light.

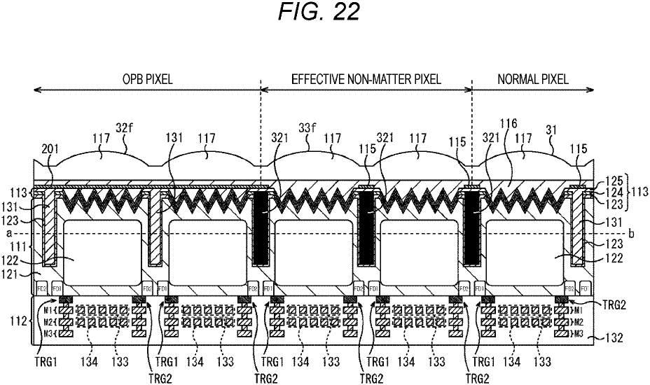

FIG. 21 is a plan view of the normal pixel 31 and the OPB pixel 32e on a line segment a-b in FIG. 20. In FIG. 21, one quadrangle represents the normal pixel 31 or the OPB pixel 32e. One normal pixel 31 is surrounded by the inter-pixel separation portion 131 filled with the material A.

One OPB pixel 32e is surrounded by the inter-pixel separation portion 301 filled with the material B, and the inter-pixel separation portion 301 is formed thicker (wider) than the inter-pixel separation portion 131. In other words, the inter-pixel separation portion 301 filled with the material B in a wide lattice shape is formed in the OPB pixel region 32e.

Also in the OPB pixel 32e according to the fifth embodiment, it is possible to suppress light leaking from the normal pixel 31 to the OPB pixel 32e and light leaking from the adjacent OPB pixel 32e.

### Sixth Embodiment

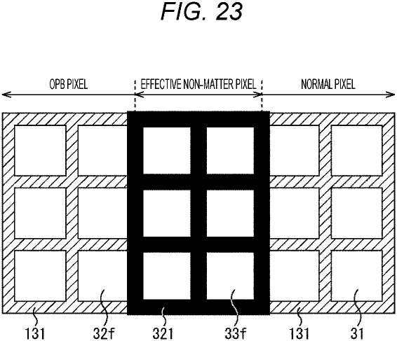

FIG. 22 is a diagram illustrating a cross-sectional configuration example of an imaging element according to the sixth embodiment. The imaging element according to the sixth embodiment is a case where the fifth embodiment is applied to a configuration in which a normal pixel region 31, an OPB pixel region 32, and an effective non-matter pixel region 33 are provided in a pixel array unit 3 as illustrated in B of FIG. 2.

The imaging element in the sixth embodiment illustrated in FIG. 22 is compared with the imaging element illustrated in FIG. 20. A configuration similar to that of the inter-pixel separation portion 301 of the OPB pixel 32e illustrated in FIG. 20 is a configuration provided in an inter-pixel separation portion 321 of an effective non-matter pixel 33f illustrated in FIG. 20.

Furthermore, in a case where the imaging element in the sixth embodiment illustrated in FIG. 22 is compared with the imaging element illustrated in FIG. 17, there is a difference in that the inter-pixel separation portion 321 of the effective non-matter pixel 33f illustrated in FIG. 22 is formed thicker than the inter-pixel separation portion 261 of the effective non-matter pixel 33c illustrated in FIG. 17, and the other points are the same.

The inter-pixel separation portion 321 of the effective non-matter pixel 33f in the sixth embodiment is formed thicker than the inter-pixel separation portion 131 of the normal pixel 31, and is filled with a material having a characteristic of absorbing light more than the inter-pixel separation portion 131.

The inter-pixel separation portion 321 of the effective non-matter pixel 33f may have a configuration (penetrating trench) penetrating the semiconductor substrate 111 as in the inter-pixel separation portion 221 (FIG. 13) of the OPB pixel 32a in the first embodiment, and the inside of the trench may be filled with a material having a characteristic of absorbing light.

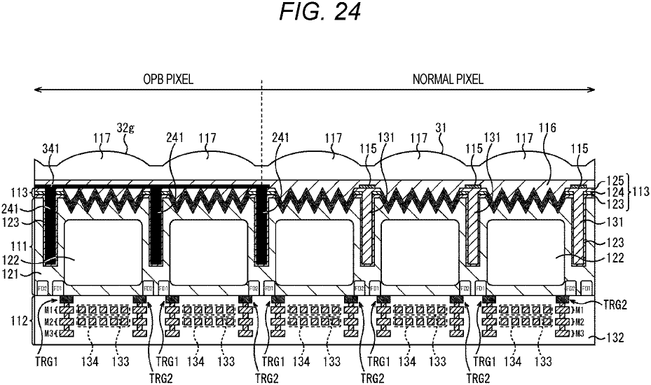

FIG. 23 is a plan view of the normal pixel 31, the OPB pixel 32f, and the effective non-matter pixel 33f on a line segment a-b in FIG. 22. In FIG. 23, one quadrangle represents the normal pixel 31, the OPB pixel 32f, or the effective non-matter pixel 33f. One normal pixel 31 is surrounded by the inter-pixel separation portion 131 filled with the material A.

In the example illustrated in FIG. 23, one OPB pixel 32f is surrounded by the inter-pixel separation portion 131 filled with the material A, similarly to one normal pixel 31. In other words, the inter-pixel separation portion 131 filled with the material A in a lattice shape is formed in the OPB pixel region 32f.

One effective non-matter pixel 33f is surrounded by the inter-pixel separation portion 321 filled with the material B, and the inter-pixel separation portion 321 is formed thicker (wider) than the inter-pixel separation portion 131. In other words, the inter-pixel separation portion 321 filled with the material B in a wide lattice shape is formed in the OPB pixel region 32f.

Also in the effective non-matter pixel 33f in the sixth embodiment, it is possible to suppress light leaking from the normal pixel 31 to the effective non-matter pixel 33f and light leaking from the adjacent effective non-matter pixel 33f. In addition, leakage of light from the effective non-matter pixel 33f to the OPB pixel 32f can be suppressed.

### Seventh Embodiment

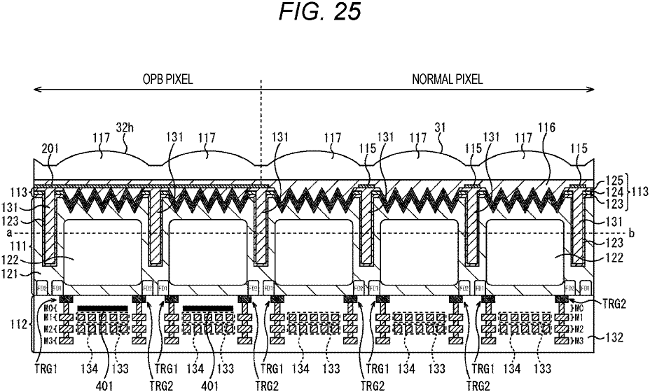

FIG. 24 is a diagram illustrating a cross-sectional configuration example of an imaging element according to the seventh embodiment. The configuration of the imaging element in the seventh embodiment is the same as the basic configuration of the imaging element in the second embodiment.

A light shielding film 341 of an OPB pixel 32g in the seventh embodiment illustrated in FIG. 24 is different from the OPB pixel 32b in the second embodiment in that the light shielding film includes the same material as the inter-pixel separation portion 241, and the other points are the same.

By forming the light shielding film 341 and the inter-pixel separation portion 241 with the same material, processing can be performed in the same process, the process at the time of manufacturing can be reduced, and the cost can be reduced.

Here, a case where the seventh embodiment is combined with the second embodiment has been described as an example. However, the seventh embodiment may be combined with the OPB pixel 32d (FIG. 19) in the fourth embodiment, or may be combined with the OPB pixel 32e (FIG. 20) in the fifth embodiment.

Also in the OPB pixel 32g in the seventh embodiment, it is possible to suppress light leaking from the normal pixel 31 to the OPB pixel 32g and light leaking from the adjacent OPB pixel 32g.

### Eighth Embodiment

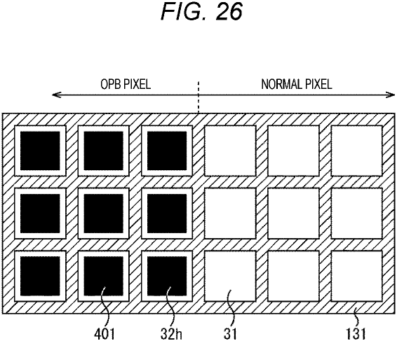

FIG. 25 is a diagram illustrating a cross-sectional configuration example of an imaging element according to the eighth embodiment. The imaging element in the eighth embodiment illustrated in FIG. 25 is compared with the imaging element illustrated in FIG. 12. The imaging element illustrated in FIG. 25 is different from the imaging element illustrated in FIG. 12 in that a 0-th metal film M0 is newly added, and the other points are the same as those of the imaging element illustrated in FIG. 12, so that the description thereof will be omitted.

In the imaging element in the eighth embodiment illustrated in FIG. 25, the 0-th metal film M0 is provided between the first metal film M1 and the semiconductor substrate 111. In the 0-th metal film M0, a light shielding member 401 is provided in a region of an OPB pixel 32h.

A metal (metal) wiring such as copper or aluminum is formed as the light shielding member 401 in a region located below the formation region of the photodiode PD of the OPB pixel 32h in the 0-th metal film M0 closest to the semiconductor substrate 111 among the 0-th to fourth metal films M of the multilayer wiring layer 112.

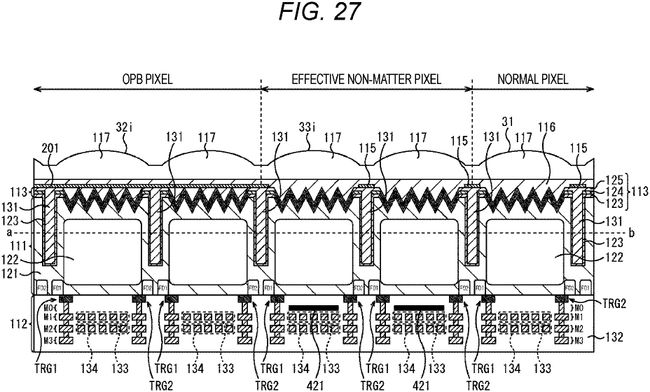

FIG. 26 is a plan view of the normal pixel 31 and the OPB pixel 32h on a line segment a-b in FIG. 25. In FIG. 26, one quadrangle represents the normal pixel 31 or the OPB pixel 32h. One normal pixel 31 and one OPB pixel 32 are each surrounded by an inter-pixel separation portion 131 filled with the material A.

In addition, FIG. 26 also illustrates the light shielding member 401. The light shielding member 401 is formed in a region at least partially overlapping a formation region of the photodiode PD of the OPB pixel 32 in plan view.

As the light shielding member 401, a material similar to the material with which the inter-pixel separation portion of the OPB pixel 32 in the above-described embodiment is filled can be used.

The light shielding member 401 shields light that has entered the semiconductor substrate 111 from the light incident surface via the on-chip lens 117 and has passed through the semiconductor substrate 111 without being photoelectric-converted in the semiconductor substrate 111, with the 0-th metal film M0 closest to the semiconductor substrate 111, and does not pass through the first metal film M1 and a second metal film M3 below the 0-th metal film M0. With this light shielding function, it is possible to prevent light that has not been photoelectric-converted in the semiconductor substrate 111 and has been transmitted through the semiconductor substrate 111 from being scattered by the metal film M below the 0-th metal film M0 and entering a neighboring pixel. As a result, it is possible to prevent light from being erroneously detected by neighboring pixels.

Furthermore, the light shielding member 401 also has a function of causing the light shielding member 401 to absorb light leaking from the adjacent normal pixel 31 or OPB pixel 32h and preventing the light from entering the photodiode PD of the OPB pixel 32h again.

Also in the OPB pixel 32h according to the eighth embodiment, it is possible to suppress light leaking from the normal pixel 31 to the OPB pixel 32h and light leaking from the adjacent OPB pixel 32h.

### Ninth Embodiment

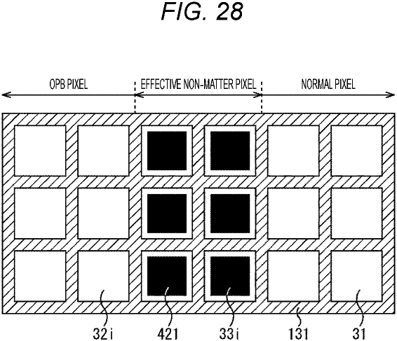

FIG. 27 is a diagram illustrating a cross-sectional configuration example of an imaging element according to the ninth embodiment. The imaging element in the ninth embodiment illustrated in FIG. 27 has a configuration in which the configuration of the OPB pixel 32h including the light shielding member 401 in the eighth embodiment is applied to an effective non-matter pixel 33i.

Also, in the imaging element in the ninth embodiment illustrated in FIG. 27, similarly to the imaging element in the eighth embodiment, the 0-th metal film M0 is provided between the first metal film M1 and the semiconductor substrate 111. Furthermore, a light shielding member 421 is provided in a region of the effective non-matter pixel 33i in the 0-th metal film M0.

A metal (metal) wiring such as copper or aluminum is formed as the light shielding member 401 in a region located below the formation region of the photodiode PD of the effective non-matter pixel 33i in the 0-th metal film M0 closest to the semiconductor substrate 111 among the 0-th to fourth metal films M of the multilayer wiring layer 112.

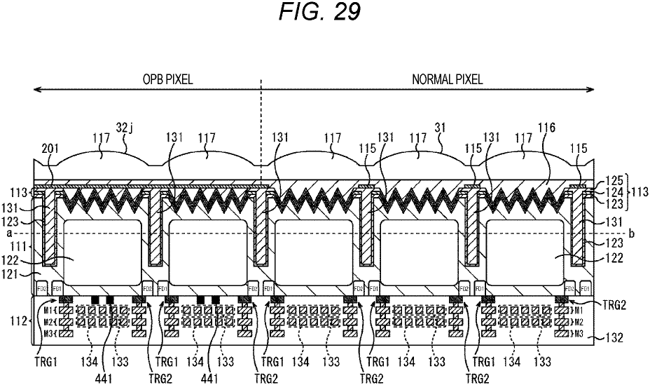

FIG. 28 is a plan view of the normal pixel 31, the OPB pixel 32i, and the effective non-matter pixel 33i on a line segment a-b in FIG. 27. In FIG. 28, one quadrangle represents the normal pixel 31, the OPB pixel 32i, or the effective non-matter pixel 33i. One normal pixel 31, one OPB pixel 32i, and one effective non-matter pixel 33i are each surrounded by the inter-pixel separation portion 131 filled with the material A.

In addition, FIG. 26 also illustrates the light shielding member 421. The light shielding member 421 is formed in a region at least partially overlapping a formation region of the photodiode PD of the effective non-matter pixel 33i in plan view.

Also in the effective non-matter pixel 33i in the eighth embodiment, it is possible to suppress light leaking from the normal pixel 31 to the effective non-matter pixel 33i and light leaking from the adjacent effective non-matter pixel 33i. In addition, light leaking from the effective non-matter pixel 33i to the OPB pixel 32i can also be suppressed.

### Tenth Embodiment

FIG. 29 is a diagram illustrating a cross-sectional configuration example of an imaging element according to the tenth embodiment. In the imaging element in the eighth embodiment and the imaging element in the ninth embodiment described above, the example has been described in which the 0-th metal film M0 is provided, and the light shielding member 401 (421) is provided in the 0-th metal film M0. The light shielding member corresponding to the light shielding member 401 (421) may be provided in a layer other than the 0-th metal film M0.

In the imaging element in the tenth embodiment illustrated in FIG. 29, a light shielding member 441 is provided in a contact layer. The contact layer is a front surface side of the semiconductor substrate 111 on which the multilayer wiring layer 112 is formed, and is a layer in which two transfer transistors TRG1 and TRG2 are formed. The light shielding member 421 may be formed in a region of the contact layer where the contact is not provided.

As illustrated in FIG. 29, the light shielding member 421 is provided in the contact layer of an OPB pixel 32j. The light shielding member 421 is not provided in the contact layer of the normal pixel 31.

Since it is not necessary to form the 0-th metal film M0 by providing the light shielding member 421 in the contact layer, the process for forming the 0-th metal film M0 can be omitted. Furthermore, since the light shielding member 421 can be formed simultaneously with the contact in the step of forming the contact in the contact layer, it can be manufactured without increasing the number of steps.

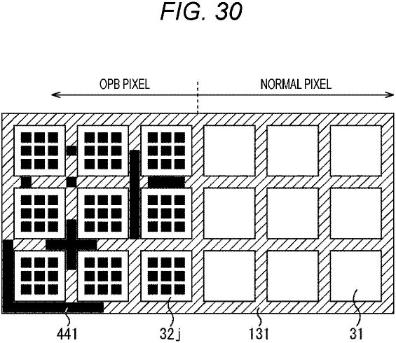

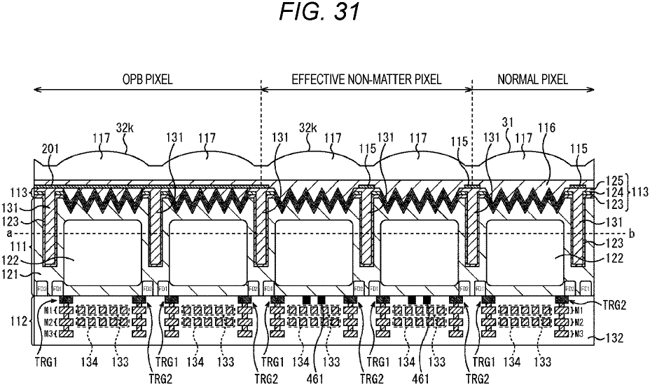

FIG. 30 is a plan view of the normal pixel 31 and the OPB pixel 32h on a line segment a-b in FIG. 29. In FIG. 30, one quadrangle represents the normal pixel 31 or the OPB pixel 32h. One normal pixel 31 and one OPB pixel 32 are each surrounded by an inter-pixel separation portion 131 filled with the material A.

FIG. 30 also illustrates the light shielding member 421. The light shielding member 421 is formed in a region at least partially overlapping a formation region of the photodiode PD of the OPB pixel 32 in plan view. In the example illustrated in FIG. 30, the light shielding member 421 formed in the region of the photodiode PD has quadrangles arranged in 3 × 3.

The shape of the light shielding member 421 is not limited to the quadrangular shape, and may be a shape other than the quadrangular shape, for example, a circular shape or a polygonal shape. In addition, the arrangement is not limited to 3 × 3, and is only required to be arranged at a position that does not affect the contact. Furthermore, the light shielding member 421 may be formed in the same shape (shape and size) as the contact, or may be formed in a different shape.

The light shielding member 421 may also be formed below the inter-pixel separation portion 131 surrounding the OPB pixel 32j. In plan view, for example, as illustrated in FIG. 30, the light shielding member 421 is also provided in a region located below the inter-pixel separation portion 131. In the example illustrated in FIG. 30, an example in which the light shielding member 421 is formed in a different shape depending on the location has been illustrated.

The light shielding member 421 may be formed in a part of a region below the inter-pixel separation portion 131, or may be formed so as to surround the OPB pixel 32j similarly to the inter-pixel separation portion 131.

The shape, size, arrangement position, and the like of the light shielding member 421 may be configured such that a predetermined pattern is repeated, or may be arranged without depending on any pattern.

Also in the OPB pixel 32j in the tenth embodiment, it is possible to suppress light leaking from the normal pixel 31 to the OPB pixel 32j and light leaking from the adjacent OPB pixel 32j.

### Eleventh Embodiment

FIG. 31 is a diagram illustrating a cross-sectional configuration example of an imaging element according to the eleventh embodiment. The imaging element in the eleventh embodiment illustrated in FIG. 31 has a configuration in which the configuration of the OPB pixel 32j including the light shielding member 421 in the tenth embodiment is applied to an effective non-matter pixel 33k.

Also, in the imaging element in the eleventh embodiment illustrated in FIG. 31, similarly to the imaging element in the tenth embodiment, a light shielding member 461 is provided in a contact layer.

The light shielding member 461 is formed in the contact layer of the effective non-matter pixel 33k. The light shielding member 441 may be formed also in the OPB pixel 32k as in the tenth embodiment.

Also in the effective non-matter pixel 33k in the eleventh embodiment, it is possible to suppress light leaking from the normal pixel 31 to the effective non-matter pixel 33k and light leaking from the adjacent effective non-matter pixel 33k. In addition, light leaking from the effective non-matter pixel 33k to the OPB pixel 32k can also be suppressed.

### Twelfth Embodiment

The first to eleventh embodiments described above can be implemented alone or in combination. For example, the inter-pixel separation portion of the OPB pixel 32 may be filled with a material different from that of the inter-pixel separation portion 131 of the normal pixel 31, and a light shielding member may be provided below the OPB pixel 32.

In addition, the inter-pixel separation portion of the effective non-matter pixel 33 may be filled with a material different from that of the inter-pixel separation portion 131 of the normal pixel 31, and a light shielding member may be provided below the effective non-matter pixel 33.

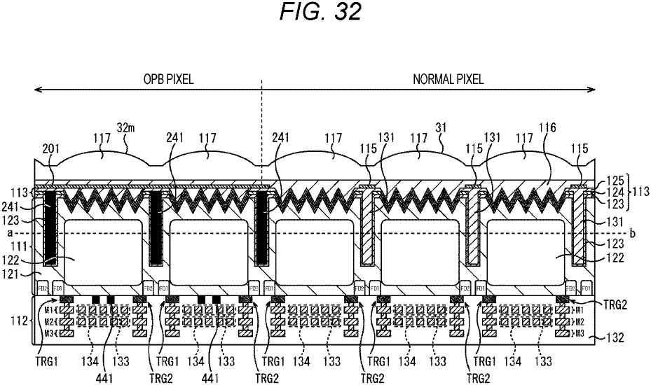

For example, FIG. 32 illustrates an imaging element of an embodiment in which the OPB pixel 32b (FIG. 15) in the second embodiment and the OPB pixel 32j in the tenth embodiment are combined. An OPB pixel 32m in the twelfth embodiment illustrated in FIG. 32 includes an inter-pixel separation portion 241 filled with a material having a high light shielding property, and includes a light shielding member 441 in a contact layer.

As described above, the first to eleventh embodiments described above can be implemented in combination. Also in the case of implementing in combination, it is possible to suppress light leaking from the normal pixel 31 to the OPB pixel 32 and the effective non-matter pixel 33 and light leaking from the adjacent OPB pixel 32 and the effective non-matter pixel 33.

As described above, in a case where the normal pixel 31 and the OPB pixel 32 are arranged in the pixel array unit 3, by configuring the inter-pixel separation portion 131 of the normal pixel 31 and the inter-pixel separation portion of the OPB pixel 32 differently, it is possible to suppress light leaking into the OPB pixel 32, and improve the accuracy of setting the black level.

More specifically, by forming the inter-pixel separation portion of the OPB pixel 32 with a material and configuration capable of further preventing leakage of light from an adjacent pixel as compared with the inter-pixel separation portion 131 of the normal pixel 31, it is possible to suppress light leaking into the OPB pixel 32, and improve the accuracy of setting the black level.

In an imaging element that receives and processes light of a long wavelength such as near-infrared light, for example, an imaging element used for distance measurement, by applying the imaging element in the above-described embodiment, it is possible to further suppress light leaking into the OPB pixel 32, and improve the accuracy of setting the black level.

### Configuration Example of Distance Measuring Module

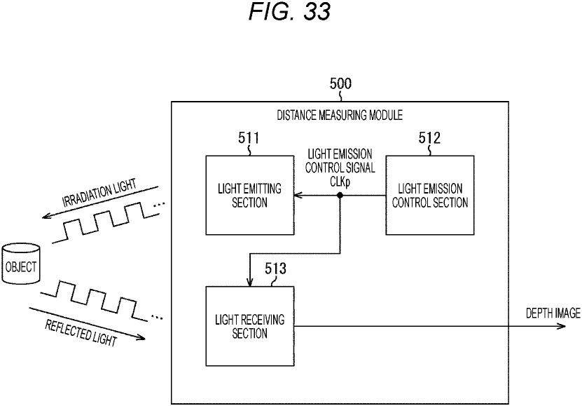

The imaging device 1 in the above-described embodiment can be applied to a device that performs distance measurement. FIG. 33 is a block diagram illustrating a configuration example of a distance measuring module that outputs distance measurement information using the above-described imaging device 1.

A distance measuring module 500 includes a light emitting section 511, a light emission control section 512, and a light receiving section 513.

The light emitting section 511 has a light source that emits light of a predetermined wavelength, and emits irradiation light of which brightness varies periodically to irradiate an object. For example, the light emitting section 511 includes a light emitting diode that emits infrared light having a wavelength in a range of 780 nm to 1000 nm as a light source, and generates irradiation light in synchronization with a rectangular wave light emission control signal CLKp supplied from the light emission control section 512.

Note that the light emission control signal CLKp is not limited to a rectangular wave as long as it is a periodic signal. For example, the light emission control signal CLKp may be a sine wave.

The light emission control section 512 supplies the light emission control signal CLKp to the light emitting section 511 and the light receiving section 513 to control the irradiation timing of the irradiation light. The frequency of the light emission control signal CLKp is, for example, 20 megahertz (MHz). Note that the frequency of the light emission control signal CLKp is not limited to 20 megahertz (MHz), and may be 5 megahertz (MHz) or the like.

The light receiving section 513 receives reflected light reflected from an object, calculates distance information for each pixel in accordance with a light reception result, generates a depth image in which a depth value corresponding to a distance to the object (subject) is stored as a pixel value, and outputs the depth image.

As the light receiving section 513, the imaging device 1 having the pixel structure of any one of the above-described embodiments is used. For example, on the basis of the light emission control signal CLKp, the imaging device 1 as the light receiving section 513 calculates distance information for each pixel from the signal intensity corresponding to the charge allocated to the floating diffusion region FD1 or FD2 of each pixel of the pixel array unit 3. Note that the number of taps of the pixel may be the above-described four taps or the like.

As described above, the imaging device 1 having the above-described pixel structure can be incorporated as the light receiving section 513 of the distance measuring module 500 that obtains and outputs the distance information to the subject by the indirect ToF method. Thus, the distance measuring characteristics as the distance measuring module 500 can be improved.

### Configuration Example of Electronic Device

The imaging device 1 can be applied not only to the distance measuring module as described above but also to various electronic devices such as an imaging device such as a digital still camera or a digital video camera having a distance measuring function, and a smartphone having a distance measuring function.

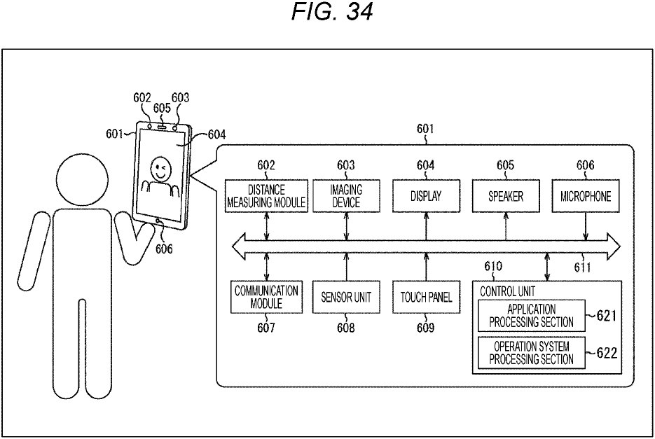

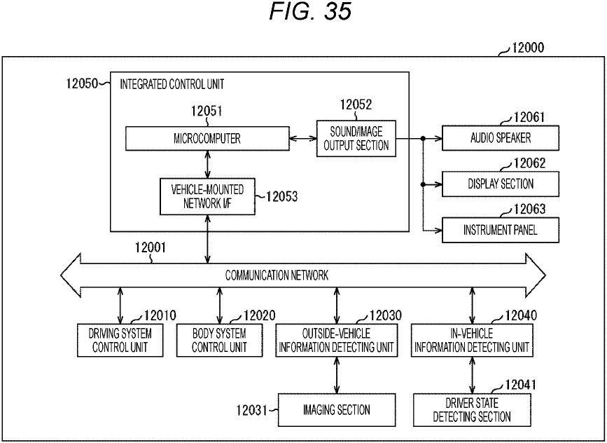

FIG. 34 is a block diagram illustrating a configuration example of a smartphone as an electronic device to which the present technology is applied.

As illustrated in FIG. 34, a smartphone 601 is configured by connecting a distance measuring module 602, an imaging device 603, a display 604, a speaker 605, a microphone 606, a communication module 607, a sensor unit 608, a touch panel 609, and a control unit 610 via a bus 611. In addition, the control unit 610 has functions as an application processing section 621 and an operation system processing section 622 by the CPU executing a program.

The distance measuring module 500 in FIG. 33 is applied to the distance measuring module 602. For example, the distance measuring module 602 is arranged on the front surface of the smartphone 601, and performs distance measurement for the user of the smartphone 601, so that the depth value of the surface shape of the face, hand, finger, or the like of the user can be output as the distance measurement result.

The imaging device 603 is arranged on the front surface of the smartphone 601, and performs imaging with the user of the smartphone 601 as a subject to acquire an image in which the user is imaged. Note that, although not illustrated, the imaging device 603 may also be disposed on the back surface of the smartphone 601.

The display 604 displays an operation screen for performing processing by the application processing section 621 and the operation system processing section 622, an image captured by the imaging device 603, and the like. For example, when a call is made by the smartphone 601, the speaker 605 and the microphone 606 output a voice of the other party and collect a voice of the user.

The communication module 607 performs network communication via the Internet, a public telephone line network, a wide area communication network for a wireless mobile body such as a so-called 4G line or a 5G line, a communication network such as a wide area network (WAN) or a local area network (LAN), short-range wireless communication such as Bluetooth (registered trademark) or near field communication (NFC), or the like. The sensor unit 608 senses speed, acceleration, proximity, and the like, and the touch panel 609 acquires a touch operation by the user on an operation screen displayed on the display 604.

The application processing section 621 performs processing for providing various services by the smartphone 601. For example, the application processing section 621 can perform processing of creating a face by computer graphics virtually reproducing the expression of the user on the basis of the depth value supplied from the distance measuring module 602 and displaying the face on the display 604. Furthermore, the application processing section 621 can perform processing of creating three-dimensional shape data of an arbitrary three-dimensional object on the basis of the depth value supplied from the distance measuring module 602, for example.

The operation system processing section 622 performs processing for realizing basic functions and operations of the smartphone 601. For example, the operation system processing section 622 can perform processing of authenticating the user’s face and unlocking the smartphone 601 on the basis of the depth value supplied from the distance measuring module 602. Furthermore, on the basis of the depth value supplied from the distance measuring module 602, the operation system processing section 622 can perform, for example, processing of recognizing a gesture of the user and processing of inputting various operations according to the gesture.

In the smartphone 601 configured as described above, by applying the above-described distance measuring module 500 as the distance measuring module 602, for example, processing of measuring and displaying the distance to a predetermined object, processing of creating and displaying three-dimensional shape data of the predetermined object, and the like can be performed.

### Application Example to Mobile Body

The technology according to the present disclosure (present technology) can be applied to various products. For example, the technology according to the present disclosure may be realized as a device mounted on any type of mobile body such as an automobile, an electric vehicle, a hybrid electric vehicle, a motorcycle, a bicycle, a personal mobility, an airplane, a drone, a ship, and a robot.

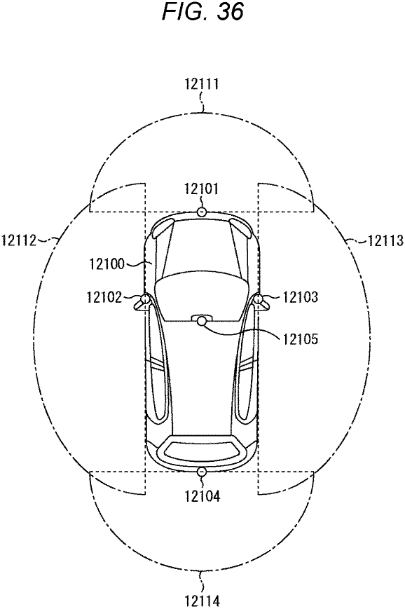

FIG. 35 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 35, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 35, an audio speaker 12061, a display section 12062, and an instrument panel 12063 are illustrated as the output device. The display section 12062 may, for example, include at least one of an on-board display and a head-up display.

FIG. 36 is a diagram depicting an example of the installation position of the imaging section 12031.

In FIG. 36, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 36 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird’s-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the present specification, the system represents the entire device including a plurality of devices.

It should be noted that an effect described in the present specification is merely an example and is not limited, and another effect may be obtained.

Note that, the embodiments of the present technology are not limited to the above-described embodiments, and various modifications can be made without departing from the gist of the present technology.

Note that, the present technology can also adopt the following configurations.

An imaging element including:
a semiconductor layer in which
a first pixel in which a read pixel signal is used to generate an image, and
a second pixel in which the read pixel signal is not used to generate an image
are arranged; and
a wiring layer stacked on the semiconductor layer,
in which a structure of the first pixel and a structure of the second pixel are different.

The imaging element according to (1), further including:
a first inter-pixel separation portion that separates the semiconductor layer of the adjacent first pixels; and
a second inter-pixel separation portion that separates the semiconductor layer of the adjacent second pixels,
in which the first inter-pixel separation portion and the second inter-pixel separation portion are provided with different structures.

The imaging element according to (2),
in which the first inter-pixel separation portion is provided so as not to penetrate the semiconductor layer, and
the second inter-pixel separation portion is provided penetrating the semiconductor layer.

The imaging element according to (2) or (3),

in which a first material with which the first inter-pixel separation portion is filled is different from a second material with which the second inter-pixel separation portion is filled.

The imaging element according to (4),

in which the second material is a material having a higher absorption coefficient of near-infrared light than the first material.

The imaging element according to any one of (2) to (5),

in which the second inter-pixel separation portion is provided to be wider than the first inter-pixel separation portion.

The imaging element according to any one of (2) to (6),

in which the second inter-pixel separation portion is provided up to a position deeper in the semiconductor layer than the first inter-pixel separation portion.

The imaging element according to any one of (2) to (7),
in which the second pixel includes a light shielding film having a high light shielding property on a light incident surface side, and
a material with which the second inter-pixel separation portion is filled and a material of the light shielding film are the same material.

The imaging element according to any one of (1) to (8),
in which the wiring layer includes at least one layer including a light shielding member, and
the light shielding member is provided so as to overlap the second pixel in plan view.

The imaging element according to (9),

in which one layer including the light shielding member is a contact layer.

The imaging element according to (9),

in which the light shielding member is provided at a lower portion of a second inter-pixel separation portion that separates the semiconductor layer of the adjacent second pixels, and is also provided in the wiring layer.

The imaging element according to any one of (1) to (11),

in which the second pixel is an optical black (OPB) pixel.

The imaging element according to any one of (1) to (12),

in which the second pixel is a pixel provided between the first pixel and an optical black (OPB) pixel.

An electronic device including:
an imaging element including
a semiconductor layer in which
a first pixel in which a read pixel signal is used to generate an image, and
a second pixel in which the read pixel signal is not used to generate an image
are arranged, and
a wiring layer stacked on the semiconductor layer,
in which a structure of the first pixel and a structure of the second pixel are different; and
a distance measuring module including
a light source that emits irradiation light whose brightness varies periodically, and
a light emission control section that controls an irradiation timing of the irradiation light.

REFERENCE SIGNS LIST

| | |
|---|---|
| 1 | Imaging device |
| 2 | Pixel |
| 3 | Pixel array unit |
| 4 | Vertical drive circuit |
| 5 | Column signal processing circuit |
| 6 | Horizontal drive circuit |
| 7 | Output circuit |
| 8 | Control circuit |
| 9 | Vertical signal line |
| 10 | Pixel drive wiring |
| 11 | Horizontal signal line |
| 12 | Semiconductor substrate |
| 13 | Input/output terminal |
| 31 | Normal pixel |
| 32 | OPB pixel |
| 33 | Effective non-matter pixel |
| 51 | Color filter layer |
| 52 | On-chip lens |
| 53 | IR cut filter |
| 54 | IR filter |
| 61 | R filter |
| 62 | B filter |
| 111 | Semiconductor substrate |
| 112 | Multilayer wiring layer |
| 113 | Antireflection film |
| 114 | Pixel boundary portion |
| 115 | Inter-pixel light shielding film |
| 116 | Flattening film |
| 117 | On-chip lens |
| 121 | Semiconductor region |
| 122 | Semiconductor region |
| 123 | Hafnium oxide film |
| 124 | Aluminum oxide film |
| 125 | Silicon oxide film |
| 131 | Inter-pixel separation portion |
| 132 | Interlayer insulating film |
| 133, 134 | Wiring |
| 151 | Antireflection film |
| 153 | PD upper region |
| 201 | Light shielding film |
| 221, 241, 261, 281, 301, 321 | Inter-pixel separation portion |
| 341 | Light shielding film |
| 401, 421, 441, 461 | Light shielding member |

1. An imaging element comprising:
a semiconductor layer in which
a first pixel in which a read pixel signal is used to generate an image, and
a second pixel in which the read pixel signal is not used to generate an image
are arranged; and
a wiring layer stacked on the semiconductor layer,
wherein a structure of the first pixel and a structure of the second pixel are different.

2. The imaging element according to claim 1, further comprising:
a first inter-pixel separation portion that separates the semiconductor layer of the adjacent first pixels; and
a second inter-pixel separation portion that separates the semiconductor layer of the adjacent second pixels,
wherein the first inter-pixel separation portion and the second inter-pixel separation portion are provided with different structures.

3. The imaging element according to claim 2,
wherein the first inter-pixel separation portion is provided so as not to penetrate the semiconductor layer, and
the second inter-pixel separation portion is provided penetrating the semiconductor layer.

4. The imaging element according to claim 2,
wherein a first material with which the first inter-pixel separation portion is filled is different from a second material with which the second inter-pixel separation portion is filled.

5. The imaging element according to claim 4,
wherein the second material is a material having a higher absorption coefficient of near-infrared light than the first material.

6. The imaging element according to claim 2,
wherein the second inter-pixel separation portion is provided to be wider than the first inter-pixel separation portion.

7. The imaging element according to claim 2,
wherein the second inter-pixel separation portion is provided up to a position deeper in the semiconductor layer than the first inter-pixel separation portion.

8. The imaging element according to claim 2,
wherein the second pixel includes a light shielding film having a high light shielding property on a light incident surface side, and
a material with which the second inter-pixel separation portion is filled and a material of the light shielding film are the same material.

9. The imaging element according to claim 1,
wherein the wiring layer includes at least one layer including a light shielding member, and
the light shielding member is provided so as to overlap the second pixel in plan view.

10. The imaging element according to claim 9,
wherein one layer including the light shielding member is a contact layer.

11. The imaging element according to claim 9,
wherein the light shielding member is provided at a lower portion of a second inter-pixel separation portion that separates the semiconductor layer of the adjacent second pixels, and is also provided in the wiring layer.

12. The imaging element according to claim 1,
wherein the second pixel is an optical black (OPB) pixel.

13. The imaging element according to claim 1,
wherein the second pixel is a pixel provided between the first pixel and an optical black (OPB) pixel.

14. An electronic device comprising:
an imaging element including
a semiconductor layer in which
a first pixel in which a read pixel signal is used to generate an image, and
a second pixel in which the read pixel signal is not used to generate an image
are arranged, and
a wiring layer stacked on the semiconductor layer,
wherein a structure of the first pixel and a structure of the second pixel are different; and
a distance measuring module including
a light source that emits irradiation light whose brightness varies periodically, and
a light emission control section that controls an irradiation timing of the irradiation light.
